(19) United States
(12) Patent Application Publication
(10) Pub. No.: US 2024/0268050 A1
(43) Pub. Date: Aug. 8, 2024

(54) REUSABLE MEMBER FOR RETAINING ELECTRONIC CARD

(71) Applicant: Amphenol Commercial Products (Chengdu) Co., Ltd., Chengdu (CN)

(72) Inventors: Peng Huang, Chengdu (CN); Luyun Yi, Chengdu (CN)

(73) Assignee: Amphenol Commercial Products (Chengdu) Co., Ltd., Chengdu (CN)

(21) Appl. No.: 18/426,628

(22) Filed: Jan. 30, 2024

(30) Foreign Application Priority Data
Feb. 3, 2023 (CN) 202310097310.9
Feb. 3, 2023 (CN) 202320105987.8
Jul. 26, 2023 (CN) 202310928643.1
Jul. 26, 2023 (CN) 202321988522.8

(51) Int. Cl. H05K 7/10; H05K 1/14

(52) U.S. Cl. CPC H05K 7/1007; H05K 1/141

(57) ABSTRACT

A reusable member configured to retain and release an add-in card to and from a motherboard without additional tools and/or processes. The add-in card has an end inserted into a connector mounted on the motherboard and another end distal from the connector. The member has a retaining portion configured to extend through the distal end of the first circuit board, and a mounting portion configured to extend through an opening of the second circuit board. The retaining portion has a sub-portion configured to move between a first position for retaining the add-in card and a second position for releasing the first circuit board. The mounting portion has a sub-portion disposed and secured in the opening of the motherboard when the member is inserted. Such a configuration enables reusing the member with circuit boards of various dimensions, without additional tools and/or processes.

### CROSS-REFERENCE TO RELATED APPLICATIONS

This application claims priority to and the benefit of Chinese Patent Application Serial No. 202321988522.8, filed on Jul. 26, 2023, entitled “LOCKING MECHANISM AND ELECTRONIC SYSTEM.” This application also claims priority to and the benefit of Chinese Patent Application Serial No. 202310928643.1, filed on Jul. 26, 2023, entitled “LOCKING MECHANISM AND OPERATING METHOD THEREOF AND ELECTRONIC SYSTEM.” This application also claims priority to and the benefit of Chinese Patent Application Serial No. 202320105987.8, filed on Feb. 3, 2023, entitled “LOCK MECHANISM AND ELECTRONIC SYSTEM.” This application also claims priority to and the benefit of Chinese Patent Application Serial No. 202310097310.9, filed on Feb. 3, 2023, entitled “LOCK MECHANISM AND METHOD OF OPERATING THE SAME, ELECTRONIC SYSTEM.” The contents of these applications are incorporated herein by reference in their entirety.

### TECHNICAL FIELD

This application relates generally to electronic systems, such as those including electrical connectors, used to interconnect electronic assemblies.

### BACKGROUND

An electronic system (e.g., smartphone, tablet computer, desktop computer, and digital camera) may be manufactured as a collection of separate electronic assemblies that are joined with electrical connectors. For example, a known architecture of an electronic system has a circuit board, typically called a motherboard, to which are mounted many electronic components. For example, in a server, the motherboard may contain a processor and supporting chips. Other electronic components, such as solid state memories, may be mounted on another circuit board separated from the motherboard, typically called a daughtercard. An end of the daughtercard may be inserted into a slot of an electrical connector mounted to the motherboard for interconnection with electronic components on the motherboard. An opposite end of the daughtercard also needs to be held in place relative to the motherboard, otherwise the connection of the daughtercard to the electrical connector is prone to loosening, resulting in an unstable connection between the daughtercard and the motherboard, which in turn affects the performance of transmitting signals and/or power between the daughtercard and the motherboard.

### BRIEF SUMMARY

Aspects of the present disclosure relate to members for retaining electronic cards. The members may be operated without tooling (i.e. “tooling-less”). The members also may be reusable. For example, the member may be mounted to a first location on a motherboard where it is positioned to retain an add-in electronic card of a first length. To configure the motherboard to accept an add-in card of a second length, the member may be removed from the first location and reused at a second location where it is positioned to retain an add-in card of the second length.

Some embodiments relate to a member configured to retain and release a first circuit board to and from a second circuit board. The member may comprise a retaining portion configured to extend through an end of the first circuit board, the retaining portion comprising a sub-portion configured to be movable with respect to the end of the first circuit board between a first position for retaining the end of the first circuit board and a second position for releasing the end of the first circuit board; and a mounting portion opposite the retaining portion and configured to extend into an opening of the second circuit board.

Optionally, the mounting portion comprises a first engaging portion configured to engage with a first surface of the second circuit board; and a second engaging portion configured to engage with a second surface of the second circuit board opposite to the first surface to secure the member to the second circuit board.

Optionally, the first engaging portion comprises a pair of beams disposed on opposite sides of the member; and the second engaging portion comprises a pair of projections protruding toward respective beams of the pair of beams.

Optionally, the sub-portion of the retaining portion comprises one or more conductive contact portions configured to make contact with a conductive portion of the first circuit board.

Optionally, the mounting portion comprises a plurality of beams configured to abut a boundary of the opening of the second circuit board so as to secure the member to the second circuit board.

Optionally, the plurality of beams are disposed in rotational symmetry.

Optionally, the sub-portion of the retaining portion comprises a protrusion disposed above a surface of the first circuit board.

Optionally, the retaining portion comprises a plurality of beams protruding away from the mounting portion to support the first circuit board.

Some embodiments relate to an electronic system. The electronic system may comprise a first circuit board; a second circuit board comprising an opening extending therethrough; and a member comprising a first portion, the first portion comprising a first sub-portion engaging the end of the first circuit board, and a second sub-portion engaging the opening of the second circuit board, wherein the first portion is insulative.

Optionally, the member comprises a semicircular portion above the platform, and a latch movable between a retained position in which the latch is above the first circuit board and a released position in which the latch is offset from the first circuit board.

Optionally, the member comprises a plurality of beams abutting a boundary of the opening of the second circuit board so as to secure the member to the second circuit board.

Optionally, the member comprises a second portion electrically coupling the first circuit board to the second circuit board.

Optionally, the second portion of the member comprises a plurality of first contact portions coupled to a conductive portion of the first circuit board and a plurality of second contact portions coupled to a conductive portion of the second circuit board.

Optionally, the first circuit board comprises a first end and a second end; the first end of the first circuit board is inserted into an electrical connector mounted on the second circuit board; and the second end of the first circuit board is secured to the second circuit board by the member.

Some embodiments relate to a method of operating a member configured for retaining and releasing a first circuit board to and from a second circuit board. The method may comprise attaching the member to the second circuit board comprising engaging a mounting portion of the member with an opening of the second circuit board; and attaching the member to a distal end of the first circuit board comprising moving a retaining portion of the member from a released position to a retained position.

Optionally, the opening is a first opening; the second circuit board comprises a second opening; and the method further comprises prior to engaging the mounting portion of the member with the first opening, removing the member from the second opening.

Optionally, attaching the member to the second circuit board comprises sliding the member along a first surface of the opening of the second circuit board and then pushing the member toward a second surface of the opening facing the first surface until that the member abuts against the second surface.

Optionally, attaching the member to a distal end of the first circuit board comprises pushing the first printed circuit board toward the second printed circuit board until that one or more portions of the member engage a surface of the first circuit board.

Optionally, engaging the mounting portion of the member with the opening of the second printed circuit board comprises compressing a plurality of beams of the member with a boundary of the opening.

Optionally, moving the retaining portion of the member from the released position to the retained position comprises rotating a retaining portion until it is adjacent and/or engages a surface of the first circuit board.

Some embodiments relate to a member configured to retain and release a first circuit board to and from a second circuit board. The member may comprise: a mounting portion configured to cooperate with an opening in the second circuit board to secure the member to the second circuit board; and a retaining portion configured to be movable between a retained position, in which the retaining portion retains an end of the first circuit board in place relative to the second circuit board, and a released position, in which the retaining portion releases the end of the first circuit board from the second circuit board, when the member is secured to the second circuit board.

Optionally, the mounting portion may comprise a first engaging portion and a second engaging portion, the first engaging portion is configured to engage with a first surface of the second circuit board and the second engaging portion is configured to engage with a second surface of the second circuit board opposite to the first surface to secure the member to the second circuit board, the first surface and the second surface of the second circuit board are substantially parallel to each other, and the opening extends from the first surface through the second circuit board to the second surface.

Optionally, the member may comprise a first member portion configured to be inserted in the opening, the first member portion may comprise a body extending along a longitudinal axis, and a first platform and a second platform respectively protruding from the body and spaced apart from each other in a direction of the longitudinal axis, the first member portion is configured such that the first platform and the second platform are positioned on two opposite sides of the second circuit board, respectively, when the first member portion is inserted in the opening, and the first platform is configured to provide the first engaging portion and the second platform is configured to provide the second engaging portion.

Optionally, the first member portion is configured to cooperate with the opening such that the first member portion can be inserted into the opening in an insertion orientation, in which the longitudinal axis is substantially perpendicular to the first surface of the second circuit board, to an installing position, in which the first platform and the second platform are respectively positioned on the two opposite sides of the second circuit board, and can move from the installing position to a installed position, in which the first engaging portion engages with the first surface of the second circuit board and the second engaging portion engages with the second surface of the second circuit board to secure the member to the second circuit board.

Optionally, the opening may comprise a first opening portion, the first member portion is configured to cooperate with the first opening portion such that when the first member portion is inserted into the first opening portion in the insertion orientation, at least one of the first platform and the second platform can pass through the first opening portion, thereby allowing the first member portion to reach the installing position.

Optionally, the opening further may comprise a second opening portion communicating with the first opening portion, the first member portion is configured to cooperate with the second opening portion such that the first member portion can translate from the installing position into the second opening portion in a direction substantially parallel to the first surface to reach the installed position, and such that the first platform and the second platform are restricted from passing through the second opening portion when the first member portion is in the installed position.

Optionally, the first member portion is configured to cooperate with the first opening portion such that the first member portion is rotatable from the installing position to the installed position about the longitudinal axis or about an axis parallel to the longitudinal axis, and such that when the first member portion is in the installed position, the first platform and the second platform are restricted from passing through the first opening portion.

Optionally, the first member portion is configured to cooperate with the first opening portion such that when the first member portion is inserted into the first opening portion in the insertion orientation, one of the first platform and the second platform is allowed to pass through the first opening portion and the other of the first platform and the second platform is restricted from passing through the first opening portion.

Optionally, the first platform includes a first platform surface and the second platform includes a second platform surface, the first platform surface serves as the first engaging portion and the second platform surface serves as the second engaging portion, such that when the first member portion is in the installed position, the first platform surface faces towards and engages with the first surface of the second circuit board and the second platform surface faces towards and engages with the second surface of the second circuit board to secure the member to the second circuit board.

Optionally, the first platform surface and the second platform surface face towards each other in the direction of the longitudinal axis such that when the first member portion is in the installed position, the first platform surface and the second platform surface sandwich therebetween a portion of the second circuit board defining the opening to secure the member to the second circuit board.

Optionally, the first platform may comprise a first platform portion and a second platform portion protruding from the body oppositely to each other, and the second platform may comprise a third platform portion and a fourth platform portion protruding from the body oppositely to each other, each of the first platform portion and the second platform portion faces a corresponding one of the third platform portion and the fourth platform portion in the direction of the longitudinal axis, such that the first platform portion and the third platform portion can sandwich therebetween a first portion of the second circuit board defining the opening, and the second platform portion and the fourth platform portion can sandwich therebetween a second portion of the second circuit board defining the opening, thereby securing the member to the second circuit board.

Optionally, the first platform may comprise a first platform surface, and the second platform may comprise a second platform surface, the first platform surface and the second platform surface face towards each other in the direction of the longitudinal axis and define a receiving slot therebetween; the second platform may comprise a protrusion protruding from the second platform surface into the receiving slot; the first platform surface of the first platform serves as the first engaging portion and the protrusion of the second platform serves as the second engaging portion such that when the first member portion is in the installed position, the first platform surface faces towards and engages with the first surface, and the second platform surface faces towards the second surface and the protrusion engages with the second surface, such that a portion of the circuit board defining the opening is sandwiched between the first platform surface and the protrusion, thereby securing the member to the second circuit board.

Optionally, the protrusion may comprise a sloped surface and an engaging surface, the protrusion is configured such that, as the first member portion moves from the installing position towards the installed position, the sloped surface can contact the second surface of the second circuit board prior to the engaging surface to guide the engagement of the second surface with the engaging surface of the protrusion.

Optionally, the retaining portion may comprise: a first sub-portion configured to support the third surface of the first circuit board at the end of the first circuit board; and a second sub-portion configured to be movable between a retained position, in which the second sub-portion engages with a fourth surface of the first circuit board opposite to the third surface at the end of the first circuit board such that the end of the first circuit board is sandwiched between the second sub-portion and the first sub-portion, and a released position, in which the second sub-portion does not engage with the fourth surface of the first circuit board, the third surface and the fourth surface of the second circuit board are substantially parallel to each other.

Optionally, the member is configured to retain the first circuit board to the second circuit board such that the third surface of the first circuit board and the first surface of the second circuit board face each other and are substantially parallel to each other; the first platform may comprise a first platform surface and a third platform surface substantially parallel to each other and opposite to each other in the direction of the longitudinal axis, the first platform surface faces towards the first surface of the second circuit board and the third platform surface faces away from the first surface of the second circuit board, when the first member portion is inserted in the opening; the first platform surface is configured to serve as the first engaging portion to engage with the first surface of the second circuit board; and the third platform surface is configured to serve as the first sub-portion to support the third surface of the first circuit board at the end of the first circuit board.

Optionally, the member further may comprise a second member portion mounted on the first member portion, the second member portion may comprise: a base secured to the body of the first member portion; and a first resilient arm extending from the base in the direction of the longitudinal axis beyond the third platform surface, the first resilient arm is configured to serve as the second sub-portion and configured to be biased from the retained position, in which the first resilient arm can engage with the fourth surface of the first circuit board at the end of the first circuit board, to the releasing position, in which the first resilient arm does not engage with the fourth surface of the first circuit board, relative to the third platform surface under the action of a force, and to return from the releasing position to the retained position after the force is withdrawn.

Optionally, the first resilient arm may comprise a fixed end connected to the base, a free end opposite to the fixed end, and a retention protrusion protruding from the free end and extending to a position above the third platform surface, the retention protrusion may comprise an engaging surface configured to engage with the fourth surface of the first circuit board at the end of the first circuit board when the first resilient arm is in the retained position.

Optionally, the retention protrusion further may comprise a sloped surface on a side opposite to the engaging surface, the sloped surface of the retention protrusion is configured to cause the first resilient arm to be biased towards the released position when a force directed towards the third platform surface in a direction of the longitudinal axis acts on the sloped surface.

Optionally, the retention protrusion protrudes from a first face of the free end at the free end, the free end is configured to cause the first resilient arm to be biased towards the released position when a force directed towards the first face acts on the first face.

Optionally, the first member portion further may comprise a positioning post protruding from the body beyond the third platform surface and configured to cooperate with a notch recessed into the first circuit board from the end of the first circuit board, such that the positioning post is received in the notch when the end of the first circuit board is supported on the third platform surface, to limit the position of the end of the first circuit board.

Optionally, the first member portion is configured to be electrically insulative and the second member portion is configured to be electrically conductive; the first circuit board may comprise a first electrically conductive portion disposed on the fourth surface at the end of the first circuit board, and the engaging surface of the retention protrusion is configured to engage with the first electrically conductive portion and establish an electrical contact with the first electrically conductive portion when the first resilient arm is in the retained position; and the second circuit board may comprise a second electrically conductive portion disposed adjacent to the opening on the first surface of the second circuit board, and the second member portion further may comprise a second resilient arm extending from the base to a position between the first platform and the second platform, the second resilient arm is configured to resiliently abut against the second electrically conductive portion to establish an electrical contact with the second electrically conductive portion, when the first member portion is in the installed position.

Optionally, the first platform surface of the first platform serves as the first engaging portion, the first platform surface faces towards and engages with the first surface of the second circuit board when the first member portion is in the installed position, the first platform may comprise a recess recessed into the first platform from the first platform surface in the direction of the longitudinal axis; and the second resilient arm may comprise a fixed end connected to the base and a free end opposite to the fixed end, the free end of the second resilient arm is received in the recess and an end portion of the free end protrudes from the first platform surface such that the free end can resiliently abut against the second electrically conductive portion when the first member portion is in the installed position.

Optionally, the mounting portion may be configured to resiliently abut against a boundary of the opening in the opening of the second circuit board to secure the member to the second circuit board.

Optionally, the member may comprise a first member portion and a second member portion mounted on the first member portion; the first member portion may comprise an insert portion extending along a longitudinal axis; the second member portion may comprise a plurality of first resilient arms disposed on the insert portion; and the insert portion and the plurality of first resilient arms are configured to be inserted in the opening of the second circuit board such that the plurality of first resilient arms resiliently abut against the boundary of the opening, thereby securing the member to the second circuit board.

Optionally, the second member portion further may comprise a body connecting the plurality of first resilient arms, each of the plurality of first resilient arms may comprise a first portion extending from the body and a second portion extending from the first portion; the first portion is configured to extend towards the insert portion in a direction substantially perpendicular to the longitudinal axis and to engage with the insert portion to retain the body on the first member portion; and the second portion is configured to extend from the first portion in a direction substantially parallel to the longitudinal axis and to bend convexly and outwardly away from the insert portion to engage with the boundary of the opening.

Optionally, the first portion may comprise a first end and a second end opposite to the first end, the first portion is connected to the body at the first end and is connected to the second portion at the second end; the insert portion may comprise an outer surface and a groove recessed into the insert portion from the outer surface in a direction substantially parallel to the longitudinal axis; and the second ends of the first portions of the plurality of first resilient arms are received in the groove of the insert portion to retain the body on the first member portion.

Optionally, the second portion extends from the second end of the first portion and may comprise a third end opposite to the second end; the intermediate portion of the second portion between the second end and the third end is bent convexly and outwardly away from the insert portion to engage with the boundary of the opening; and when the intermediate portion is biased inwardly towards the insert portion, the second end can engage with a wall of the groove and the third end can engage with the outer surface of the insert portion to provide support to the intermediate portion against the bias.

Optionally, the body is annular and is disposed around the insert portion.

Optionally, the plurality of first resilient arms are arranged rotationally symmetrically about the longitudinal axis.

Optionally, the retaining portion may comprise: a first sub-portion configured to support a third surface of the first circuit board at the end of the first circuit board; and a second sub-portion configured to be movable between a retained position, in which the second sub-portion engages with a fourth surface of the first circuit board opposite to the third surface at the end of the first circuit board such that the end of the first circuit board is sandwiched between the second sub-portion and the first sub-portion, and a released position, in which the second sub-portion does not engage with the fourth surface of the first circuit board, the third surface and the fourth surface of the second circuit board are substantially parallel to each other.

Optionally, the second member portion further may comprise a first sub-portion on a side of the body opposite to the plurality of first resilient arms; the first member portion further may comprise a sub-portion, the sub-portion may comprise a body extending from the insert portion in the direction of the longitudinal axis beyond the first sub-portion of the second member portion, and a protrusion protruding from the body, the protrusion is configured to serve as the second sub-portion; and the first member portion and the second member portion are configured such that the first member portion is rotatable in the opening of the second circuit board when the insert portion and the plurality of first resilient arms are inserted in the opening, such that the protrusion is movable between a retained position, in which the protrusion engages with the fourth surface of the first circuit board at the end of the first circuit board such that the end of the first circuit board is sandwiched between the protrusion and the first sub-portion, and a released position, in which the protrusion does not engage with the fourth surface of the first circuit board.

Optionally, the first member portion is configured to be electrically insulative and the second member portion is configured to be electrically conductive; the first circuit board may comprise a first electrically conductive portion disposed on the third surface at the end of the first circuit board, and the first sub-portion engages with the first electrically conductive portion and establishes an electrical contact with the first electrically conductive portion when the first sub-portion supports the third surface of the first circuit board; and the insert portion and the plurality of first resilient arms are configured to be inserted into the opening from the first surface of the second circuit board, the opening extends from the first surface through the first circuit board to a second surface of the first circuit board opposite to the first surface, the first surface and the second surface are substantially parallel to each other, the second circuit board may comprise a second electrically conductive portion disposed on the first surface adjacent to the opening; and when the insert portion and the plurality of first resilient arms are inserted in the opening to secure the member to the second circuit board, the insert portion presses against a portion of the first portion between the first end and the second end such that the portion of the first portion is pressed against the second electrically conductive portion of the second circuit board and establishes an electrical contact with the second electrically conductive portion.

Optionally, the first sub-portion of the first member portion may comprise a plurality of second resilient arms extending from the body.

Optionally, the body of the sub-portion is configured to cooperate with a notch recessed into the first circuit board from the end of the first circuit board, such that the body is received in the notch when the end of the first circuit board is supported on the first sub-portion, to limit the position of the end of the first circuit board.

Optionally, the first circuit board may comprise a third electrically conductive portion disposed in the opening on the boundary of the opening, the second portion engages with the third electrically conductive portion and establishes an electrical contact with the third electrically conductive portion when the plurality of first resilient arms are inserted in the opening.

Optionally, the first portion is further configured to interfere with the first surface of the second circuit board when the insert portion and the plurality of first resilient arms are inserted into the opening from the first surface of the second circuit board, so as to limit further insertion of the insert portion and the plurality of first resilient arms into the opening when the second portion is inserted into the opening.

Optionally, the end of the first circuit board is a first end of the first circuit board and the first circuit board further may comprise a second end opposite to the first end, the first circuit board is connected to the second circuit board at the second end by an electrical connector.

Some embodiments relate to an electronic system. The electronic system may comprise: a first circuit board; a second circuit board; and the member described herein, wherein the member is secured to the second circuit board and retains an end of the first circuit board in place relative to the second circuit board.

Some embodiments relate to a method of operating a member configured to retain and release a first circuit board to and from a second circuit board. The method may comprise: cooperating a mounting portion of the member with an opening of the second circuit board to secure the member to the second circuit board; placing a retaining portion of the member in a released position and disposing the first circuit board on the retaining portion; and moving the retaining portion from the released position to a retained position to retain an end of the first circuit board in place relative to the second circuit board.

Optionally, cooperating the mounting portion of the member with the opening of the second circuit board may comprise engaging a first engaging portion of the mounting portion with a first surface of the second circuit board, and engaging a second engaging portion of the mounting portion with a second surface of the second circuit board, to secure the member to the second circuit board, wherein the first surface and the second surface of the second circuit board are substantially parallel to each other, the opening extends from the first surface through the second circuit board to the second surface.

Optionally, the member may comprise a first member portion, the first member portion may comprise a body extending along a longitudinal axis, and a first platform and a second platform respectively protruding from the body and spaced apart from each other in a direction of the longitudinal axis, the first platform is configured to provide the first engaging portion, and the second platform is configured to provide the second engaging portion; and cooperating the mounting portion of the member with the opening of the second circuit board may comprise inserting the first member portion in the opening such that the first platform and the second platform are positioned on two opposite sides of the second circuit board, respectively.

Optionally, cooperating the mounting portion of the member with the opening of the second circuit board may comprise inserting the first member portion into the opening in an insertion orientation, in which the longitudinal axis is substantially perpendicular to the first surface of the second circuit board, to an installing position, in which the first platform and the second platform are respectively positioned on the two opposite sides of the second circuit board, and moving the first member portion from the installing position to a installed position, in which the first engaging portion engages with the first surface of the second circuit board and the second engaging portion engages with the second surface of the second circuit board.

Optionally, inserting the first member portion in the insertion orientation into the opening to the installing position may comprise inserting the first member portion in the insertion orientation into the first opening portion of the opening such that the first platform and the second platform are positioned on the two opposite sides of the second circuit board, respectively; and moving the first member portion from the installing position to the installed position may comprise translating the first member portion from the installing position in a direction substantially parallel to the first surface into a second opening portion of the opening communicating with the first opening portion.

Optionally, inserting the first member portion in the insertion orientation into the opening to the installing position may comprise inserting the first member portion in the insertion orientation into the first opening portion of the opening such that the first platform and the second platform are positioned on the two opposite sides of the second circuit board, respectively; and moving the first member portion from the installing position to the installed position may comprise rotating the first member portion from the installing position to the installed position about the longitudinal axis or about an axis parallel to the longitudinal axis.

Optionally, placing the retaining portion in the released position may comprise placing a second sub-portion of the retaining portion in a releasing position in which the second sub-portion does not engage with a fourth surface of the first circuit board; and disposing the first circuit board on the retaining portion may comprise supporting a third surface of the first circuit board opposite to the fourth surface at the end of the first circuit board with a first sub-portion of the retaining portion, wherein the third surface and the fourth surface of the second circuit board are substantially parallel to each other.

Optionally, the third surface of the first circuit board and the first surface of the second circuit board face towards each other and substantially parallel to each other when the first circuit board is disposed on the retaining portion; the first platform may comprise a first platform surface and a third platform surface substantially parallel to each other and opposite to each other in the direction of the longitudinal axis, the first platform surface is configured to serve as the first engaging portion and the third platform surface is configured to serve as the first sub-portion; cooperating the mounting portion of the member with the opening of the second circuit board may comprise inserting the first member portion in the opening such that the first platform surface faces towards and engages with the first surface of the second circuit board; and placing the first circuit board on the retaining portion may comprise supporting the third surface of the first circuit board at the end of the first circuit board with the third platform surface.

Optionally, the member further may comprise a second member portion mounted on the first member portion, the second member portion may comprise: a base secured on the body of the first member portion; and a first resilient arm extending from the base in the direction of the longitudinal axis beyond the third platform surface, the first resilient arm is configured to serve as the second sub-portion and is configured to be biased from the retained position, in which the first resilient arm can engage with the fourth surface of the first circuit board at the end of the first circuit board, to the releasing position, in which the first resilient arm does not engage with the fourth surface of the first circuit board, relative to the third platform surface under the action of a force, and to return from the releasing position to the retained position under the action of its own resiliency after the force is withdrawn; placing the second sub-portion of the retaining portion in the released position may comprise applying a biasing force to bias the first resilient arm to the released position.

Optionally, the first resilient arm may comprise a fixed end connected to the base, a free end opposite to the fixed end, and a retention protrusion protruding from the free end and extending to a position above the third platform surface, the retention protrusion may comprise an engaging surface and a sloped surface on a side opposite to the engaging surface, the engaging surface of the retention protrusion is configured to engage with the fourth surface of the first circuit board at the end of the first circuit board when the first resilient arm is in the retained position, the sloped surface of the retention protrusion is configured such that the first resilient arm is biased towards the released position when a force directed towards the third platform surface along the direction of the longitudinal axis acts on the sloped surface; and biasing the first resilient arm to the released position may comprise pressing the end of the first circuit board against the sloped surface from the side of the retention protrusion of the sloped surface to bias the first resilient arm to the released position.

Optionally, the first resilient arm may comprise a fixed end connected to the base, a free end opposite to the fixed end, and a retention protrusion protruding from the free end and extending to a position above the third platform surface, the retention protrusion may comprise an engaging surface, the engaging surface of the retention protrusion is configured to engage with the fourth surface of the first circuit board at the end of the first circuit board when the first resilient arm is in the retained position; the first member portion is configured to be electrically insulative and the second member portion is configured to be electrically conductive; the first circuit board may comprise a first electrically conductive portion disposed on the fourth surface at the end of the first circuit board, and the engaging surface of the retention protrusion is configured to engage with the first electrically conductive portion and to establish an electrical contact with the first electrically conductive portion when the first resilient arm is in the retained position; the second circuit board may comprise a second electrically conductive portion disposed adjacent to the opening on the first surface of the second circuit board, and the second member portion further may comprise a second resilient arm extending from the base to a position between the first platform and the second platform, the second resilient arm is configured to resiliently abut against the second electrically conductive portion when the first member portion is in the installed position, to establish an electrical contact with the second electrically conductive portion; moving the retaining portion from the released position to the retained position may comprise withdrawing the biasing force to return the first resilient arm to the retained position so as to engage the engaging surface of the retention protrusion with the first electrically conductive portion; and moving the first member portion from the installing position to the installed position may comprise resiliently abutting the second resilient arm against the second electrically conductive portion.

Optionally, cooperating the mounting portion of the member with the opening of the second circuit board may comprise causing the mounting portion to resiliently abut against the boundary of the opening in the opening of the second circuit board.

Optionally, the member may comprise a first member portion and a second member portion mounted on the first member portion, the first member portion may comprise an insert portion extending along a longitudinal axis, the second member portion may comprise a plurality of first resilient arms disposed on the insert portion; and cooperating the mounting portion of the member with the opening of the second circuit board may comprise inserting the insert portion and the plurality of first resilient arms in the opening of the second circuit board to resiliently abut the plurality of first resilient arms against the boundary of the opening.

Optionally, placing the retaining portion in the released position may comprise placing the second sub-portion of the retaining portion in a releasing position, in which the second sub-portion does not engage with the fourth surface of the first circuit board; and disposing the first circuit board on the retaining portion may comprise supporting a third surface of the first circuit board opposite to the fourth surface at the end of the first circuit board with a first sub-portion of the retaining portion, wherein the third surface and the fourth surface of the second circuit board are substantially parallel to each other.

Optionally, the second member portion further may comprise a body connecting the plurality of first resilient arms, and a first sub-portion on a side of the body opposite to the plurality of first resilient arms; the first member portion further may comprise a sub-portion, the sub-portion may comprise a body extending from the insert portion in the direction of the longitudinal axis beyond the first sub-portion of the second member portion, and a protrusion protruding from the body, the protrusion is configured to serve as the second sub-portion; the first member portion and the second member portion are configured such that the first member portion is rotatable in the opening of the second circuit board when the insert portion and the plurality of first resilient arms are inserted in the opening, to enable the protrusion to move between a retained position, in which the protrusion engages with the fourth surface of the first circuit board at the end of the first circuit board such that the end of the first circuit board is sandwiched between the protrusion and the first sub-portion, and a released position, in which the protrusion does not engage with the fourth surface of the first circuit board; and moving the retaining portion from the released position to the retained position may comprise rotating the first member portion in the opening of the second circuit board to move the protrusion to the retained position.

Optionally, the first member portion is configured to be electrically insulative and the second member portion is configured to be electrically conductive; each of the plurality of first resilient arms may comprise a first portion extending from the body and a second portion extending from the first portion; the first portion is configured to extend towards the insert portion in a direction substantially perpendicular to the longitudinal axis and to engage with the insert portion to retain the body on the first member portion; the second portion is configured to extend from the first portion in a direction substantially parallel to the longitudinal axis and to bend convexly and outwardly away from the insert portion to engage with the boundary of the opening; the first circuit board may comprise a first electrically conductive portion disposed on the third surface at the end of the first circuit board, and the first sub-portion engages with the first electrically conductive portion and establishes an electrical contact with the first electrically conductive portion, when the third surface of the first circuit board is supported by the first sub-portion; and the insert portion and the plurality of first resilient arms are configured to be inserted into the opening from the first surface of the second circuit board, the opening extends from the first surface through the first circuit board to a second surface of the first circuit board opposite to the first surface, the first surface and the second surface are substantially parallel to each other, the second circuit board may comprise a second electrically conductive portion disposed on the first surface adjacent to the opening; disposing the first circuit board on the retaining portion may comprise engaging the first sub-portion with the first electrically conductive portion of the first circuit board and establishing an electrical contact with the first electrically conductive portion; and cooperating the mounting portion of the member with the opening of the second circuit board may comprise inserting the insert portion and the plurality of first resilient arms into the opening such that the insert portion presses against a portion of the first portion between the first end and the second end to enable that the portion of the first portion is pressed against the second electrically conductive portion of the second circuit board and establishes an electrical contact with the second electrically conductive portion.

Some embodiments relate to a member. The member may comprise a second member portion and a first member portion connectable to the second member portion in a rotatable manner, wherein the first member portion may comprise a columnar portion that extends in a vertical direction and a stop portion that protrudes from at least a portion of an upper portion of the columnar portion, the second member portion may comprise a cylindrical portion formed to extend in a vertical direction, and the cylindrical portion may be sleeved on an outer side of the columnar portion of the first member portion such that the columnar portion is rotatable with respect to the cylindrical portion to enable the member to be switched between a locked position and an unlocked position.

Optionally, the first member portion may comprise a distal end provided with the stop portion, a proximal end opposite to the distal end, and a connecting flange provided between the distal end and the proximal end. A guide portion may be provided at an upper portion of the connecting flange, the guide portion comprises a guide surface extending in a plane substantially perpendicular to the vertical direction, and a first stop portion and a second stop portion extending in the vertical direction, and the guide portion may be formed as a semi-annular step portion; and the cylindrical portion may comprise a protruding portion which is movable along the guide surface between the first stop portion and the second stop portion during the rotation of the columnar portion with respect to the cylindrical portion, the protruding portion abuts against the first stop portion when the member is in the unlocked position, and the protruding portion abuts against the second stop portion when the member is in the locked position.

Optionally, the first stop portion and the second stop portion may be spaced apart from each other by 180 degrees in a circumferential direction of the columnar portion.

Optionally, the connecting flange may comprise a recess provided adjacent to the second stop portion, and the recess extends through the connecting flange in the vertical direction.

Optionally, the stop portion of the first member portion may protrude in a horizontal direction towards a side on which the guide portion is located and is tapered in a direction away from an axis of rotation of the first member portion.

Optionally, the cylindrical portion may be formed to have a substantially square shape, a central axis of the cylindrical portion may coincide with an axis of rotation of the columnar portion, the cylindrical portion may comprise a first sidewall and a second sidewall opposite to the first sidewall in a transverse direction perpendicular to the vertical direction, and the protruding portion may be provided at a central portion of an upper edge portion of the first sidewall and protrude towards an inner side of the cylindrical portion.

Optionally, the cylindrical portion may comprise a third sidewall and a fourth sidewall opposite to the third sidewall in a horizontal direction perpendicular to the vertical direction and the transverse direction, the third sidewall may be provided with a first cantilever portion and a second cantilever section which may both extend along a plane perpendicular to the vertical direction and may be spaced apart from each other, and the first cantilever portion may be provided above the second cantilever portion in the vertical direction.

Optionally, the first cantilever portion and the second cantilever portion may have the following cross-sectional shapes in a cross-section perpendicular to the vertical direction: semi-circular, trapezoidal, sectoral, square, or irregular shapes.

Optionally, the second member portion may further comprise a first resilient portion extending downwards in the vertical direction at a central portion of the first sidewall, and a second resilient portion extending downwards in the vertical direction at a central portion of the second sidewall, and the first resilient portion and the second resilient portion are mirrored about a plane perpendicular to the transversal direction and passing through a transverse central axis of the second member portion, and the first member portion may be provided with a first engagement portion and a second engagement portion associated with the first resilient portion and the second resilient portion.

Optionally, the first resilient portion may comprise a first end connected to a lower edge portion of the first sidewall, a second end opposite to the first end, and an arch portion provided between the first end and the second end, and when the member is in the unlocked position or the locked position, the second end of the first resilient portion cooperates with the first engagement portion or the second engagement portion of the first member portion.

Optionally, a first concave portion may be provided at the second end of the first resilient portion and a second concave portion may be provided at the second end of the second resilient portion; and the first engagement portion of the first member portion may comprise a first convex portion provided adjacent to the proximal end, the second engagement portion of the first member portion may comprise a second convex portion provided adjacent to the proximal end, and the first convex portion and the second convex portion are provided to be spaced apart from each other by 180 degrees in a circumferential direction of the first member portion, wherein when the member is in the locked position or the unlocked position, one of the first concave portion and the second concave portion is engaged with the first convex portion, and the other of the first concave portion and the second concave portion is engaged with the second convex portion.

Optionally, a strip portion extending downward in the vertical direction may be formed at a lower edge portion of the fourth sidewall of the cylindrical portion, and during the rotation of the first member portion with respect to the second member portion, a free end of the strip portion is capable of being in contact with and sliding past the first convex portion or the second convex portion.

Optionally, a plurality of protruding ribs are provided adjacent to the proximal end of the first member portion, the plurality of protruding ribs are arranged in a circumferential direction on an outer peripheral portion of the columnar portion of the first member portion and protrude outward in a radial direction, and the plurality of protruding ribs are provided at a radially inner side of the cylindrical portion in a projection plane of the member perpendicular to the vertical direction.

Optionally, the columnar portion may comprise a mounting portion provided in the vertical direction between the connecting flange and the protruding rib, and the connecting flange and the protruding rib extend in the radial direction beyond of an outer circumferential surface of the mounting portion.

Optionally, the first member portion may be configured to be electrically insulating and the second member portion may be configured to be electrically conductive.

Some embodiments relate to an electronic system. The electronic system may comprise: a first printed circuit board; a second printed circuit board; and a member which may be configured for retaining the first printed circuit board in a releasable manner to the second printed circuit board, wherein the first printed circuit board may comprise a notch provided for insertion of the member at a first end of the first printed circuit board, and the second printed circuit board may comprise an opening for insertion of the member. The member is movable in a rotatable manner between a locked position in which the member may be inserted through the notch of the first printed circuit board and the opening of the second printed circuit board and is non-removable with respect to the first printed circuit board and the second printed circuit board to retain the first end of the first printed circuit board to be fixed with respect to the second printed circuit board, and an unlocked position in which the member is insertable in a removable manner through the notch of the first printed circuit board and the opening of the second printed circuit board, and the first end of the first printed circuit board is not fixed with respect to the second printed circuit board.

Optionally, the member may comprise a first member portion which may comprise a columnar portion extending in a vertical direction and a stop portion protruding from at least a portion of an upper portion of the columnar portion, the first member portion is rotatable such that at least a portion of the stop portion extends in a horizontal direction beyond the notch on an upper surface of the first printed circuit board to prevent a first end of the first printed circuit board from moving in a vertical direction, and thus the member is in the locked position, and the first member portion is rotatable such that the stop portion moves away from an upper surface of the first printed circuit board, and thus the member is in the unlocked position.

Optionally, the member may comprise a second member portion which may comprise a cylindrical portion formed to extend in the vertical direction, and the cylindrical portion may be sleeved on an outer side of the columnar portion of the first member portion such that the columnar portion is rotatable with respect to the cylindrical portion, and when the member is inserted through the notch of the first printed circuit board and the opening of the second printed circuit board, the cylindrical portion is arranged between the first printed circuit board and the second printed circuit board.

Optionally, the first member portion may comprise a distal end provided with the stop portion, a proximal end opposite to the distal end, and a connecting flange provided between the distal end and the proximal end, a guide portion may be provided at an upper portion of the connecting flange, the guide portion may comprise a guide surface extending in a plane substantially perpendicular to the vertical direction, and a first stop portion and a second stop portion extending in the vertical direction, and the guide portion is formed as a semi-annular step portion. The cylindrical portion may comprise a protruding portion which is movable along the guide surface between the first stop portion and the second stop portion during the rotation of the columnar portion with respect to the cylindrical portion. The protruding portion may abut against the first stop portion when the member is in the unlocked position, and the protruding portion may abut against the second stop portion when the member is in the locked position.

Optionally, the first stop portion and the second stop portion may be spaced apart from each other by 180 degrees in a circumferential direction of the columnar portion.

Optionally, the connecting flange may comprise a recess provided adjacent to the second stop portion, the recess extending through the connecting flange in the vertical direction.

Optionally, the stop portion of the first member portion protrudes in a horizontal direction towards a side on which the guide portion is located and is tapered in a direction away from an axis of rotation of the first member portion.

Optionally, the cylindrical portion may comprise a first sidewall and a second sidewall opposite to the first sidewall in a transverse direction perpendicular to the vertical direction, and the protruding portion may be provided at a central portion of an upper edge portion of the first sidewall and protrude towards an inner side of the cylindrical portion.

Optionally, the cylindrical portion may comprise a third sidewall and a fourth sidewall opposite to the third sidewall in a horizontal direction perpendicular to the vertical direction and the transverse direction, the third sidewall may be provided with a first cantilever portion and a second cantilever section which both extend along a plane perpendicular to the vertical direction and are spaced apart from each other, and the first cantilever portion is provided above the second cantilever portion in the vertical direction, wherein the first cantilever portion may comprise a first surface and a second surface opposite to the first surface, the second cantilever portion may comprise a third surface facing the second surface of the first cantilever portion and a fourth surface opposite to the third surface, and when the member is inserted through the notch of the first printed circuit board and the opening of the second printed circuit board, the first surface of the first cantilever portion may rest against a lower surface of the first printed circuit board, and the fourth surface of the second cantilevered portion may rest against an upper surface of the second printed circuit board.

Optionally, the first cantilever portion and the second cantilever portion may have the following cross-sectional shapes in a cross-section perpendicular to the vertical direction: semi-circular, trapezoidal, sectoral, square, or irregular shapes.

Optionally, the second member portion may further comprise a first resilient portion extending downwards in the vertical direction at a central portion of the first sidewall, and a second resilient portion extending downwards in the vertical direction at a central portion of the second sidewall, and the first resilient portion and the second resilient portion are mirrored about a plane perpendicular to the transversal direction and passing through a transverse central axis of the second member portion, and the first member portion may be provided with a first engagement portion and a second engagement portion associated with the first resilient portion and the second resilient portion, and when the member is in the unlocked position or the locked position, one of the first resilient portion and the second resilient portion is engaged with the first engagement portion and the other of the first resilient portion and the second resilient portion is engaged with the second engagement portion.

Optionally, the first resilient portion may comprise a first end connected to a lower edge portion of the first sidewall, a second end opposite to the first end, and an arch portion provided between the first end and the second end, and when the member is in the unlocked position or the locked position, the second end of the first resilient portion may cooperate with the first engagement portion or the second engagement portion of the first member portion.

Optionally, a first concave portion may be provided at the second end of the first resilient portion and a second concave portion may be provided at the second end of the second resilient portion; the first engagement portion of the first member portion may comprise a first convex portion provided at the proximal end, the second engagement portion of the first member portion may comprise a second convex portion provided at the proximal end, and the first convex portion and the second convex portion are provided to be spaced apart from each other by 180 degrees in a circumferential direction of the first member portion, wherein when the member is in the locked position or the unlocked position, one of the first concave portion and the second concave portion is engaged with the first convex portion, and the other of the first concave portion and the second concave portion is engaged with the second convex portion.

Optionally, a strip portion extending downward in the vertical direction may be formed at a lower edge portion of the fourth sidewall of the cylindrical portion, and during the rotation of the first member portion with respect to the second member portion, a free end of the strip portion is capable of being in contact with and sliding past the first convex portion or the second convex portion.

Optionally, a plurality of protruding ribs may be provided adjacent to the proximal end of the first member portion, the plurality of protruding ribs are arranged in a circumferential direction on an outer peripheral portion of the columnar portion of the first member portion and protrude outward in a radial direction, and when the member is inserted through the opening of the second printed circuit board, an upper surface of the protruding rib in the vertical direction is at least partially in contact with a lower surface of the second printed circuit board.

Optionally, the columnar portion may comprise a mounting portion corresponding to the opening of the second printed circuit board, the mounting portion may be provided between the connecting flange and the protruding ribs in the vertical direction, an inner surface of the opening of the second printed circuit board comprises a plurality of rotational position-limiting portions capable of being in contact with an outer circumferential surface of the mounting portion, at least one of the plurality of rotational position-limiting portions is formed to have an arcuate shape, and the mounting portion may be dimensioned in the vertical direction to correspond to a thickness of the second printed circuit board.

Optionally, the opening of the second printed circuit board may have a first elongate portion and a second elongate portion perpendicular to the first elongate portion, and when the member is inserted through the opening of the second printed circuit board and is in the unlocked position or in the locked position, a dimension of the member in the transverse direction may correspond to a dimension of the first elongate portion in the transverse direction and, in a projection plane of the electronic system perpendicular to the vertical direction, the strip portion of the second member portion is arranged in the second elongate portion of the opening.

Optionally, the first member portion may be configured to be electrically insulating and the second member portion may be configured to be electrically conductive.

Optionally, the first printed circuit board may comprise a first electrically conductive portion provided on a lower surface of the first printed circuit board and adjacent to the notch, and when the member is inserted through the notch of the first printed circuit board and the opening of the second printed circuit board, a first surface of the first cantilever portion of the second member portion is engaged with the first electrically conductive portion and establishes an electrical contact with the first electrically conductive portion.

Optionally, the second printed circuit board may comprise a second electrically conductive portion provided on an upper surface of the second printed circuit board and adjacent to the opening, and when the member is inserted through the notch of the first printed circuit board and the opening of the second printed circuit board, a fourth surface of the second cantilevered portion of the second member portion may be engaged with the second electrically conductive portion and establish an electrical contact with the second electrically conductive portion.

Some embodiments relate to a method for operating a member. The method may comprise: providing a first panel, a notch being provided at a first end of the first panel; providing a second panel, an opening being provided in the second panel; providing a member which is movable in a rotatable manner between a locked position and an unlocked position; aligning the member in a vertical direction with the notch of the first panel and the opening of the second panel; rotating the member to the unlocked position, and inserting the member through the notch of the first panel and the opening of the second panel, and rotating the member to the locked position so that the member is irremovable with respect to the first panel and the second panel, thereby retaining the first end of the first panel to be fixed with respect to the second panel.

Optionally, providing the member may comprise: configuring the member to comprise a first member portion comprising a columnar portion extending in a vertical direction, and a stop portion protruding from at least a portion of an upper portion of the columnar portion; rotating the member to the locked position comprises: the first member portion is rotated such that at least a portion of the stop portion extends in a horizontal direction beyond the notch on an upper surface of the first panel to prevent a first end of the first panel from moving in a vertical direction, and thus the member is in the locked position, and rotating the member to the unlocked position may comprise: the first member portion is rotated such that the stop portion moves away from an upper surface of the first panel, and thus the member is in the unlocked position.

Optionally, providing the member may comprise: configuring the member to comprise a second member portion comprising a cylindrical portion formed to extend in the vertical direction, the cylindrical portion being sleeved on an outer side of the columnar portion of the first member portion, and inserting the member through the notch of the first panel and the opening of the second panel may comprise: arranging the cylindrical portion between the first panel and the second panel.

Optionally, providing the member may comprise: configuring the first member portion to comprise a guide portion provided along an outer circumferential portion of the first member portion, the guide portion comprising a guide surface extending in a plane substantially perpendicular to the vertical direction, the guide portion comprising a first stop portion and a second stop portion extending in the vertical direction; and configuring the second member portion to comprise a protruding portion protruding towards an inner side of the second member portion; and rotating the member to the locked position comprises: rotating the first member portion with respect to the second member portion in such a way that the protruding portion moves away from the first stop portion along the guide surface until the protruding portion abuts against the second stop portion.

Optionally, providing the member may comprise: configuring the cylindrical portion of the member to comprise a first sidewall and a second sidewall opposite to the first sidewall in a transverse direction perpendicular to the vertical direction, and providing the protruding portion at a central portion of an upper edge portion of the first sidewall, and configuring the cylindrical portion of the second member portion to comprise a third sidewall and a fourth sidewall opposite to the third sidewall in a horizontal direction, the third sidewall being provided with a first cantilever portion and a second cantilever portion which both extend in a plane perpendicular to the vertical direction and are spaced apart from each other, the first cantilever portion being provided above the second cantilever portion in the vertical direction, the first cantilever portion comprising a first surface and a second surface opposite to the first surface, the second cantilever portion comprising a third surface facing the second surface of the first cantilever portion and a fourth surface opposite to the third surface; and inserting the member through the notch of the first panel and the opening of the second panel may comprise: resting the first surface of the first cantilever portion against a lower surface of the first panel; and resting the fourth surface of the second cantilever portion against an upper surface of the second panel.

Optionally, the method may comprise: rotating the member to the unlocked position to remove the member from the notch of the first panel and the opening of the second panel, when the first end of the first panel is retained to be fixed with respect to the second panel.

Optionally, the method may comprise: configuring the first panel as a first printed circuit board, and configuring the second panel as a second printed circuit board.

These techniques may be used alone or in any suitable combination. The foregoing summary is provided by way of illustration and is not intended to be limiting.

### BRIEF DESCRIPTION OF DRAWINGS

The accompanying drawings may not be drawn to scale. In the drawings, each identical or nearly identical component that is illustrated in various figures may be represented by a like numeral. For purposes of clarity, not every component may be labeled in every drawing. In the drawings:

FIG. 1 is a perspective view of an electronic system including a member, an electrical connector, a first circuit board, and a second circuit board, illustrating the member in a retained position, according to some embodiments;

FIG. 2 is a partially exploded perspective view of the electronic system of FIG. 1;

FIG. 3 is another perspective view of the electronic system of FIG. 1;

FIG. 4 is a side view of the electronic system of FIG. 1;

FIG. 5 is a top partial perspective view of the electronic system of FIG. 1, with the first circuit board hidden and a first member portion of the member in an installing position;

FIG. 6 is a bottom partial perspective view of the electronic system of FIG. 5;

FIG. 7 is a top partial perspective view of the electronic system of FIG. 1, with the first circuit board hidden and the first member portion of the member in an installed position;

FIG. 8 is a bottom partial perspective view of the electronic system of FIG. 7;

FIGS. 9A and 9B are perspective views of the member of FIG. 1;

FIGS. 10A and 10B are perspective views of the first member portion of the member of FIGS. 9A and 9B;

FIGS. 11A and 11B are perspective views of a second member portion of the member of FIGS. 9A and 9B;

FIG. 12 is a perspective view of an electronic system including a member, an electrical connector, a first circuit board, and a second circuit board, according to another embodiment of the present application, with the member in a retained position;

FIG. 13 is a perspective view of the electronic system of FIG. 12, with the member in a released position;

FIG. 14 is a partially exploded perspective view of the electronic system of FIG. 12;

FIG. 15 is a side view of the electronic system of FIG. 12;

FIGS. 16A and 16B are perspective views of the member of FIG. 12;

FIGS. 17A and 17B are perspective views of a first member portion of the member of FIGS. 16A and 16B;

FIGS. 18A and 18B are perspective views of a second member portion of the member of FIGS. 16A and 16B;

FIG. 18C is a top view of the second member portion of FIG. 18A and FIG. 18B; and

FIG. 18D is a cross-sectional view of the second member portion of FIG. 18C taken along line I-I in FIG. 18C.

FIG. 19 is a perspective view of an electronic system, according to some embodiments, with a member in a retained position.

FIG. 20 is a partially exploded perspective view of the electronic system of FIG. 19.

FIG. 21 is a perspective view of a first printed circuit board of the electronic system of FIG. 19.

FIG. 22 is a top view of the electronic system of FIG. 19, with the member in a released position.

FIG. 23 is a top view of the electronic system of FIG. 19.

FIG. 24 is a side view of the electronic system of FIG. 19.

FIG. 25 is a perspective view of the member of the electronic system of FIG. 19, according to some embodiments.

FIG. 26 is another perspective view of the member of FIG. 25.

FIG. 27 is a perspective view of a second member portion of the member of FIG. 25.

FIG. 28 is another perspective view of the second member portion of FIG. 27.

FIG. 29 is a perspective view of a first member portion of the member of FIG. 25.

FIG. 30 is another perspective view of the first member portion of FIG. 29.

FIG. 31 is a partial side view of the electronic system of FIG. 19 in a locked position.

FIG. 32 is a partial cross-sectional view of the electronic system of FIG. 31 taken along a line marked C-C in FIG. 31.

### DETAILED DESCRIPTION

The inventors have recognized and appreciated design techniques for reusable locking members that can be used to retain and release subassemblies to and from electronic systems without additional tools and/or processes. The subassemblies may include add-in cards that may serve various functions including, for example, solid state drive (SSD) cards, wireless communication cards, radio frequency modules, etc. An add-in card may have an end inserted in an electrical connector mounted on a printed circuit board such as a motherboard, and another end distal from the electrical connector. The Inventors have recognized and appreciated that the distal ends of add-in cards are conventionally retained to the motherboard through, for example, the assistance of additional tooling required for screws or the like, and/or additional processes such as soldering. These conventional designs also make it difficult to release an add-in card from a system. The techniques described herein may enable retaining and releasing add-in cards of various dimensions without additional tools and/or processes.

Some embodiments of the present application are described in detail below in conjunction with the accompanying drawings. It should be appreciated that these embodiments are not intended to limit the present application. Moreover, features in the embodiments of the present application may be combined with each other.

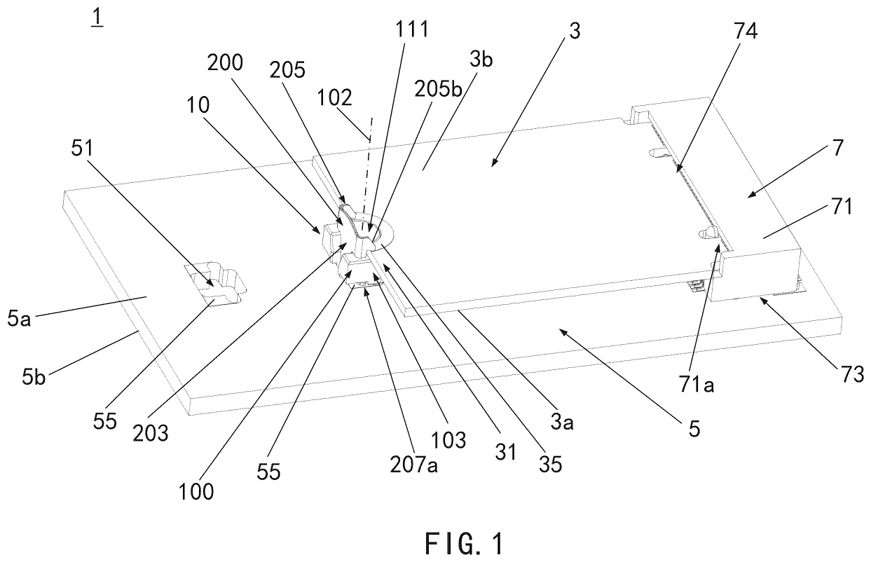

FIGS. 1 to 11B schematically illustrate an electronic system 1 according to an embodiment of the present application. As shown in FIGS. 1 to 8, the electronic system 1 includes a first circuit board 3, a second circuit board 5, an electrical connector 7, and a member 10.

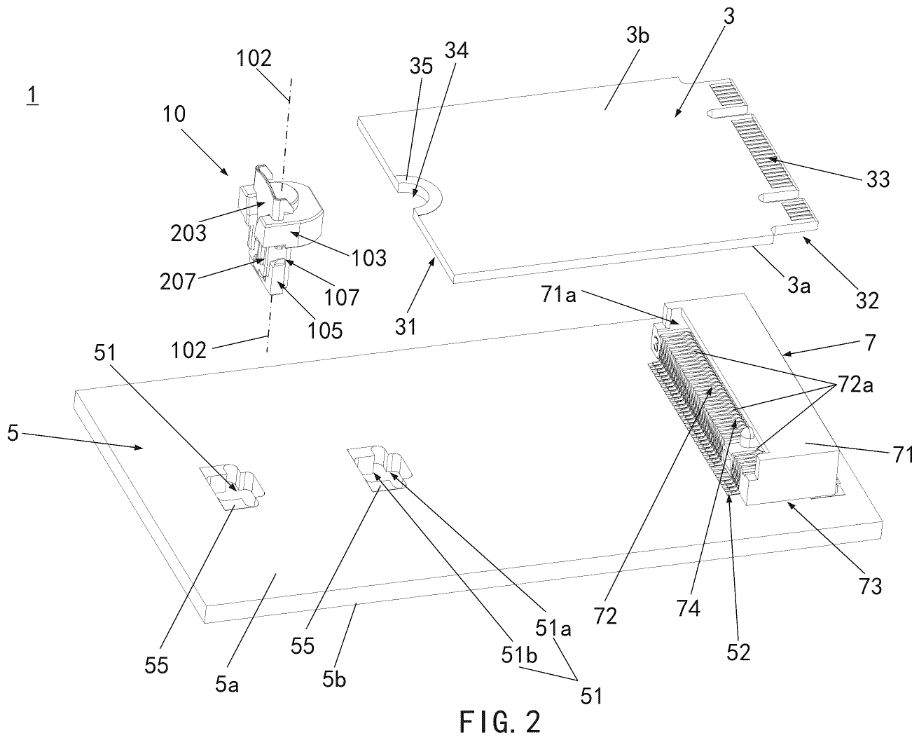

The first circuit board 3 may also be referred to as a “first printed circuit board” or “first PCB”, which may be, for example, a daughtercard such as a solid state drive (SSD) card, a wireless communication card, a radio frequency module. As shown in FIG. 2, the first circuit board 3 may include a first end 31, a second end 32 opposite to the first end 31, a third surface 3a and a fourth surface 3b. The third surface 3a and the fourth surface 3b may be opposite to each other and substantially parallel to each other. The first circuit board 3 may further include a conductive portion (e.g., a conductive pad) 33 disposed at or near an edge of the first circuit board 3 at the second end 32, and may optionally include a notch 34 recessed into the first circuit board 3 at the first end 31. The notch 34 may extend from the third surface 3a through the first circuit board 3 to the fourth surface 3b.

The second circuit board 5 may also be referred to as a “second printed circuit board” or “second PCB”, which may, for example, be a motherboard. As shown in FIG. 2, the second circuit board 5 may include a first surface 5a and a second surface 5b. The first surface 5a and the second surface 5b may be opposite to each other and substantially parallel to each other. The second circuit board 5 may further include a conductive portion 52 disposed on the first surface 5a. The conductive portion 52 may be, for example, a conductive pad or a conductive through-hole. As will be described in detail below, the conductive portion 52 is configured to be connected with the electrical connector 7. The second circuit board 5 may further include at least one opening 51. Two openings 51 are shown in FIGS. 1 to 3 and 5 to 8, both of which have the same structures but at different distances from the conductive portion 52. As will be described in detail below, providing the two openings 51 allows the second circuit board 5 to mate with daughtercards of different lengths. It should be appreciated that the second circuit board 5 may include one opening or more than two openings, and that the present application is not limited thereto. Each opening 51 extends from the first surface 5a through the second circuit board 5 to the second surface 5b. That is, each opening 51 extends through the second circuit board 5.

The electrical connector 7 may be configured to connect the first circuit board 3 and the second circuit board 5 to enable signal and/power transfer between the first circuit board 3 and the second circuit board 5. As shown in FIGS. 1 and 3 to 4, the first circuit board 3 and the second circuit board 5 are configured to be disposed in orientations substantially parallel to each other such that the first surface 5a of the second circuit board 5 and the third surface 3a of the first circuit board 3 face towards each other and are substantially parallel to each other, and such that the second surface 5b of the second circuit board 5 and the fourth surface 3b of the first circuit board 3 face away from each other and are substantially parallel to each other.

As shown in FIG. 2, the electrical connector 7 may include a housing 71, a plurality of conductive terminals 72 disposed in the housing 71, a mounting interface 73, and a mating interface 74.

The electrical connector 7 may be configured to be mounted on the first surface 5a of the second circuit board 5 at the mounting interface 73 such that the plurality of conductive terminals 72 establish electrical connections with the conductive portion 52 on the first surface 5a at the mounting interface 73. As an example, in the case where the conductive portion 52 of the second circuit board 5 is a conductive pad(s), the plurality of conductive terminals 72 may be soldered to the conductive pad(s) by surface mounting technique. As another example, in the case where the conductive portion 52 of the second circuit board 5 are conductive through-holes, the plurality of conductive terminals 72 may be press-fitted into the conductive through-holes.

The electrical connector 7 may also be configured to mate with the first circuit board 3 at the mating interface 74 such that the plurality of conductive terminals 72 establish electrical connections with the conductive portion 33 of the first circuit board 3 at the mating interface 74. In some embodiments, the housing 71 of the electrical connector 7 may include a slot 71a at the mating interface 74, and contact portions 72a of the plurality of conductive terminals 72 may be exposed in the slot 71a. The second end 32 of the first circuit board 3 may be inserted into the slot 71a of the electrical connector 7 such that the contact portions 72a of the plurality of conductive terminals 72 establish electrical contact with the conductive portion 33 of the first circuit board 3. In this way, the electrical connector 7 is capable of mechanically and electrically connecting the first circuit board 3 and the second circuit board 5, enabling signal and/power transmission between the first circuit board 3 and the second circuit board 5. That is, the first circuit board 3 is capable of being connected to the second circuit board 5 at the second end 32 via the electrical connector 7. The electrical connector 7 is capable of retaining the second end 32 of the first circuit board 3 relative to the second circuit board 5.

It should be appreciated that although the electrical connector 7 is shown as a single-piece connector, the specific form of the electrical connector 7 is not limited thereto. For example, the electrical connector 7 may be a two-piece connector composed of a plug connector and a receptacle connector. Further, it should be appreciated that the electrical connector 7 may include any suitable mechanism or feature that facilitates securing the electrical connector 7 to the second circuit board 5, and/or any suitable mechanism or feature that facilitates connecting the first circuit board 3 to the electrical connector 7.

The member 10 may be configured for retaining and releasing the first circuit board 3 to and from the second circuit board 5. As will be described in detail below, the member 10 may include a mounting portion and a retaining portion. The mounting portion may be configured to mate with the opening 51 of the second circuit board 5 to secure the member 10 to the second circuit board 5. The retaining portion may be configured to move between a retained position, in which the retaining portion retains the first end 31 of the first circuit board 3 in place relative to the second circuit board 5, and a released position, in which the retaining portion releases the first end 31 of the first circuit board 3 from the second circuit board 5, when the member 10 is secured to the second circuit board 5. The member 10 can help to reliably retain the first circuit board 3 to the second circuit board 5 to improve the stability of the connection between the first circuit board 3 and the second circuit board 5, and can facilitate the assembly and disassembly of the first circuit board 3 to and from the second circuit board 5.

In some embodiments, as will be described in detail below, the mounting portion may include a first engaging portion and a second engaging portion. The first engaging portion may be configured to engage with the first surface 5a of the second circuit board 5 and the second engaging portion may be configured to engage with the second surface 5b of the second circuit board 5 to secure the member 10 to the second circuit board 5. That is, the first engaging portion and the second engaging portion may be configured to engage with the first surface 5a and the second surface 5b of the second circuit board 5 on two opposite sides of the second circuit board 5, respectively, so as to secure the member 10 to the second circuit board 5.

In one of these embodiments, as shown in FIGS. 1 to 10B, the member 10 may include a first member portion 100 configured to be inserted in the opening 51 of the second circuit board 5. The first member portion 100 may include a body 101 extending along a longitudinal axis 102, and a first platform 103 and a second platform 105 protruding from the body 101, respectively, and spaced apart from each other in a direction of the longitudinal axis 102. The first member portion 100 may be configured such that when the first member portion 100 is inserted in the opening 51 of the second circuit board 5, the first platform 103 and the second platform 105 are disposed on the two opposite sides of the second circuit board 5, respectively. In particular, the first platform 103 is positioned at a side of the first surface 5a of the second circuit board 5, and the second platform 105 is positioned at a side of the second surface 5b of the second circuit board 5. As will be described in detail below, the first platform 103 may be configured to provide the aforementioned first engaging portion and the second platform 105 may be configured to provide the aforementioned second engaging portion.

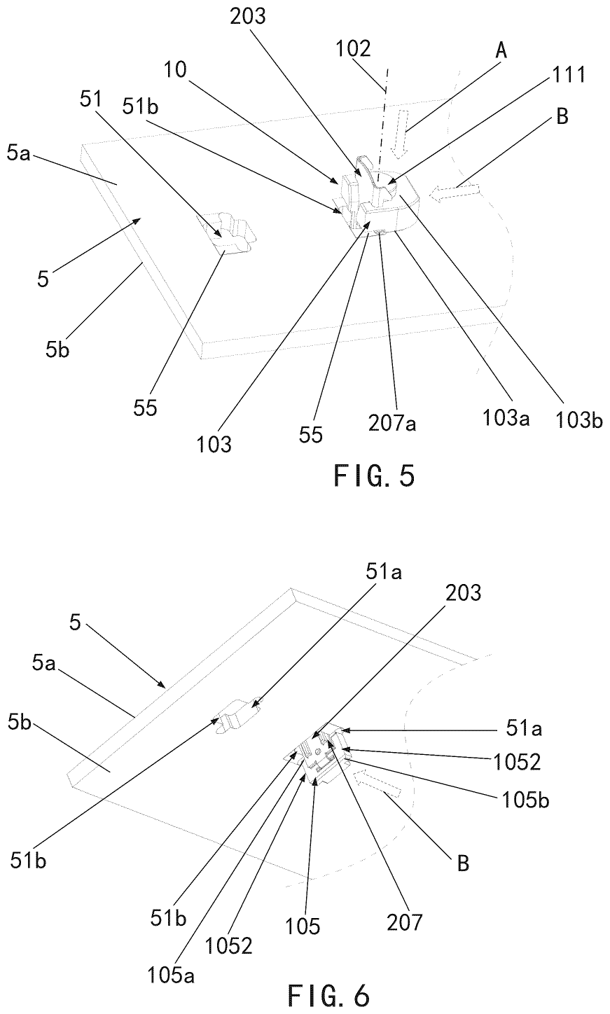

The first member portion 100 may be configured to cooperate with the opening 51 of the second circuit board 5 such that the first member portion 100 can be inserted into the opening 51 in an insertion orientation, in which the longitudinal axis 102 is substantially perpendicular to the first surface 5a (and the second surface 5b, as described above, the first surface 5a and the second surface 5b are substantially parallel to each other) of the second circuit board 5, to an installing position (the process is schematically indicated by a dashed arrow A in FIG. 5), and can move from the installing position to an installed position (the process is schematically indicated by dashed arrows B in FIGS. 5 and 6).

FIGS. 1, 3 to 4, and 7 to 8 illustrate that the first member portion 100 is in the installed position, FIGS. 5 to 6 illustrate that the first member portion 100 is in the installing position, and FIG. 2 illustrates that the first member portion 100 is removed from the opening 51 of the second circuit board 5. With the first member portion 100 in the installing position as shown in FIGS. 5 to 6, the first platform 103 and the second platform 105 are positioned on the two opposite sides of the second circuit board 5, respectively. As will be described in detail below, with the first member portion 100 in the installed position as shown in FIGS. 1, 3 to 4, and 7 to 8, the first engaging portion provided by the first platform 103 engages with the first surface 5a of the second circuit board 5 and the second engaging portion provided by the second platform 105 engages with the second surface 5b of the second circuit board 5 to secure the member 10 to the second circuit board 5.

As shown in FIG. 2, the opening 51 of the second circuit board 5 may include a first opening portion 51a. The first member portion 100 may be configured to cooperate with the first opening portion 51a such that when the first member portion 100 is inserted into the first opening portion 51a in the insertion orientation described above, at least one of the first platform 103 and the second platform 105 can pass through the first opening portion 51a, thereby allowing the first member portion 100 to reach the installing position. That is, when the first member portion 100 is aligned with the first opening portion 51a in the insertion orientation, the first opening portion 51a can completely cover the positive projection of the at least one of the first platform 103 and the second platform 105 in a direction substantially perpendicular to the first surface 5a of the second circuit board 5, such that the at least one of the first platform 103 and the second platform 105 can pass through the first opening portion 51a when the first member portion 100 is inserted into the first opening portion 51a in the insertion orientation, such that the first platform 103 is positioned on a side of the first surface 5a of the second circuit board 5 and the second platform 105 is positioned on a side of the second surface 5b of the second circuit board 5.

In one of these embodiments, the first member portion 100 may be configured to cooperate with the first opening portion 51a such that when the first member portion 100 is inserted into the first opening portion 51a in the insertion orientation, one of the first platform 103 and the second platform 105 is allowed to pass through the first opening portion 51a, while the other of the first platform 103 and the second platform 105 is restricted from passing through the first opening portion 51a. That is, when the first member portion 100 is aligned with the first opening portion 51a in the insertion orientation, the first opening portion 51a can completely cover the positive projection of the one of the first platform 103 and the second platform 105 in a direction substantially perpendicular to the first surface 5a of the second circuit board 5 (in other words, the positive projection of the one of the first platform 103 and the second platform 105 in the direction substantially perpendicular to the first surface 5a of the second circuit board 5 is within the first opening portion 51a), and does not overlap at least partially with the positive projection of the other of the first platform 103 and the second platform 105 in the direction substantially perpendicular to the first surface 5a of the second circuit board 5 (in other words, the positive projection of the other of the first platform 103 and the second platform 105 in the direction substantially perpendicular to the first surface 5a of the second circuit board 5 goes at least partially beyond the first opening portion 51a), such that when the first member portion 100 is inserted into the first opening 51a in the insertion orientation, the one of the first platform 103 and the second platform 105 is allowed to pass through the first opening 51a, while the other of the first platform 103 and the second platform 105 is blocked by the second circuit board 5 and is thus restricted from passing through the first opening portion 51a. With such a configuration, a unidirectional insertion of the first member portion 100 can be achieved to prevent the first member portion 100 from being inserted in an improper orientation into the first opening 51a. In the case where the first platform 103 is allowed to pass through the first opening 51a, the first member portion 100 can be inserted from the second surface 5b of the second circuit board 5 into the first opening 51a to reach the installing position. In the case where the second platform 105 is allowed to pass through the first opening portion 51a, the first member portion 100 may be inserted from the first surface 5a of the second circuit board 5 into the first opening portion 51a to reach the installing position.

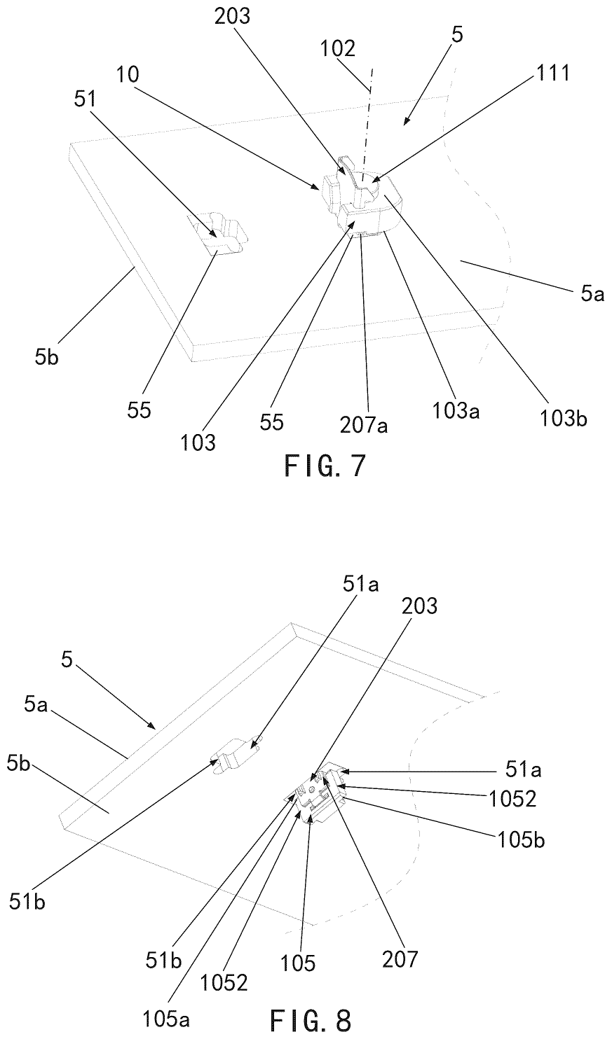

In some embodiments, as schematically illustrated in FIGS. 5 to 8, the first member portion 100 may be configured to translate from the installing position to the installed position in a direction substantially parallel to the first surface 5a. The process is indicated schematically by arrows B in FIGS. 5 and 6. As shown in FIG. 2, the opening 51 of the second circuit board 5 may further include a second opening portion 51b communicating with the first opening portion 51a. For example, the second opening portion 51b may extend from the first opening portion 51a in a direction substantially parallel to the first surface 5a and away from the conductive portion 52 of the second circuit board 5. It should be appreciated that the present application is not limited thereto. The first member portion 100 may be configured to cooperate with the second opening portion 51b such that the first member portion 100 can translate from the installing position shown in FIGS. 5 and 6 in the direction substantially parallel to the first surface 5a into the second opening portion 51b and to the installed position shown in FIGS. 7 and 8. The second opening portion 51b may be configured to receive therein a portion of the body 101 of the first member portion 100 between the first platform 103 and the second platform 105 to allow the first member portion 100 to be translatable from the installing position to the installed position.

The first member portion 100 may further be configured to cooperate with the second opening portion 51b such that the first platform 103 and the second platform 105 are restricted from passing through the second opening portion 51b when the first member portion 100 is in the installed position. In other words, when the first member portion 100 is in the installed position, the second opening portion 51b does not overlap at least partially with the positive projection of the first platform 103 in a direction substantially perpendicular to the first surface 5a of the second circuit board 5, and does not overlap at least partially with the positive projection of the second platform 105 in the direction substantially perpendicular to the first surface 5a of the second circuit board 5, such that the first platform 103 and the second platform 105 are blocked by the second circuit board 5 and are thus restricted from passing through the second opening portion 51b.

It should be appreciated that the first member portion 100 can also be translated from the installed position shown in FIGS. 7 and 8 to the installing position shown in FIGS. 5 and 6 in a direction opposite to the aforementioned direction substantially parallel to the first surface 5a, and removed from the first opening portion 51a from the installing position in a direction substantially perpendicular to the first surface 5a of the second circuit board 5.

With such a configuration, the member 10 can be secured to and removed from the second circuit board 5 by the first member portion 100 without additional tools and/or processes. Compared to fixing to the circuit board with additional tools required by such as screws and/or additional processes such as soldering, the structure of the present application facilitates mounting and removal and enables reusability. The first member portion 100 enables the member 10 to be easily removed from one opening 51 of the second circuit board 5 and subsequently easily installed into another opening 51 of the second circuit board 5, thereby facilitating cooperating with first circuit boards 3 of different lengths.

It should be appreciated that in some other embodiments, the first member portion 100 may be configured to rotate from the installing position to a installed position about the longitudinal axis 102 or about an axis parallel to the longitudinal axis 102. In particular, the first member portion 100 may be configured to cooperate with the first opening portion 51a such that when the first member portion 100 is in the installing position, the first member portion 100 can be rotated from the installing position about the longitudinal axis 102 or about an axis parallel to the longitudinal axis 102 to the installed position. The first opening portion 51a may be configured to allow a portion of the body 101 of the first member portion 100 between the first platform 103 and the second platform 105 to rotate therein to allow the first member portion 100 to rotate from the installing position to the installed position. The first member portion 100 may further be configured to cooperate with the first opening portion 51a such that the first platform 103 and the second platform 105 are restricted from passing through the first opening portion 51a when the first member portion 100 is in the installed position. That is, when the first member portion 100 is rotated to the installed position, the first opening portion 51a does not overlap at least partially with the positive projection of the first platform 103 in a direction substantially perpendicular to the first surface 5a of the second circuit board 5, and does not overlap at least partially with the positive projection of the second platform 105 in the direction substantially perpendicular to the first surface 5a of the second circuit board 5, such that the first platform 103 and the second platform 105 are blocked by the second circuit board 5 and are thus restricted from passing through the second opening portion 51b. In this case, it is possible to eliminate the second opening portion 51b of the opening 51 of the circuit board 5.

As shown in FIGS. 4 and 9A to 10B, the first platform 103 may include a first platform surface 103a and a third platform surface 103b. The first platform surface 103a and the third platform surface 103b may be configured to be substantially parallel to each other and opposite to each other in the direction of the longitudinal axis 102. When the first member portion 100 is inserted in the opening 51 of the second circuit board 5, the first platform surface 103a faces towards the first surface 5a of the second circuit board 5 and the third platform surface 103b faces away from the first surface 5a of the second circuit board 5. The second platform 105 may include a second platform surface 105a and a fourth platform surface 105b. The second platform surface 105a and the fourth platform surface 105b may be configured to be substantially parallel to each other and opposite to each other in the direction of the longitudinal axis 102. When the first member portion 100 is inserted in the opening 51, the second platform surface 105a faces towards the second surface 5b of the second circuit board 5 and the fourth platform surface 105b faces away from the second surface 5b of the second circuit board 5. In some embodiments, the first platform surface 103a and the third platform surface 103b of the first platform 103 are parallel to the second platform surface 105a and the fourth platform surface 105b of the second platform 105.

In some embodiments, as shown in FIGS. 4 and 9A to 10B, the first platform surface 103a of the first platform 103 and the second platform surface 105a of the second platform 105 may face towards each other in the direction of the longitudinal axis 102. That is, the positive projections of the first platform surface 103a of the first platform 103 and the second platform surface 105a of the second platform 105 in the direction of the longitudinal axis 102 entirely or partially overlap with each other. In this case, the first platform surface 103a of the first platform 103 and the second platform surface 105a of the second platform 105 may define a receiving slot S therebetween.

In one of these embodiments, as shown in FIGS. 4 and 9A to 10B, the second platform 105 may include a protrusion 107 protruding from the second platform surface 105a into the receiving slot S. In this case, the first platform surface 103a of the first platform 103 serves as the first engaging portion and the protrusion 107 of the second platform 105 serves as the second engaging portion, such that when the first member portion 100 is in the installed position, the first platform surface 103a faces towards and engages with the first surface 5a of the second circuit board 5, and the second platform surface 105a faces towards the second surface 5b and the protrusion 107 engages with the second surface 5b of the second circuit board 5, such that a portion of the second circuit board 5 defining the opening 51 (e.g., a portion defining the second opening portion 51b of the opening 51) is sandwiched between the first platform surface 103a and the protrusion 107 to enable that the member 10 is secured to the second circuit board 5. The protrusion 107 is capable of deforming when engaging with the second surface 5b of the second circuit board 5, which enables that the portion of the second circuit board 5 defining the opening 51 is reliably sandwiched between the first platform surface 103a and the protrusion 107, thereby increasing the reliability of securing the member 10 to the second circuit board 5.

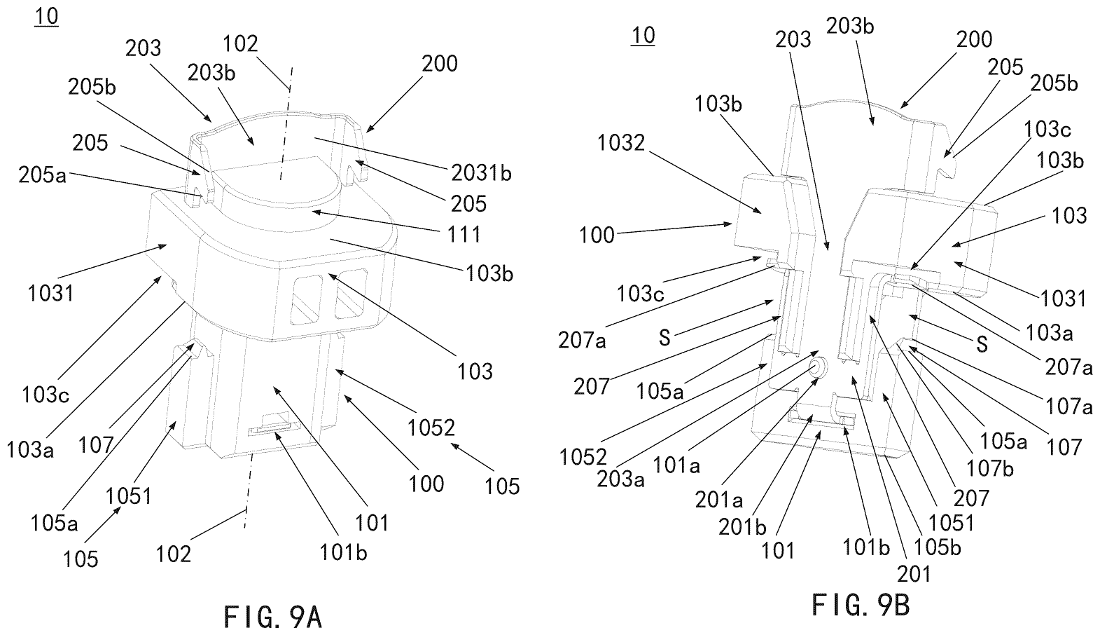

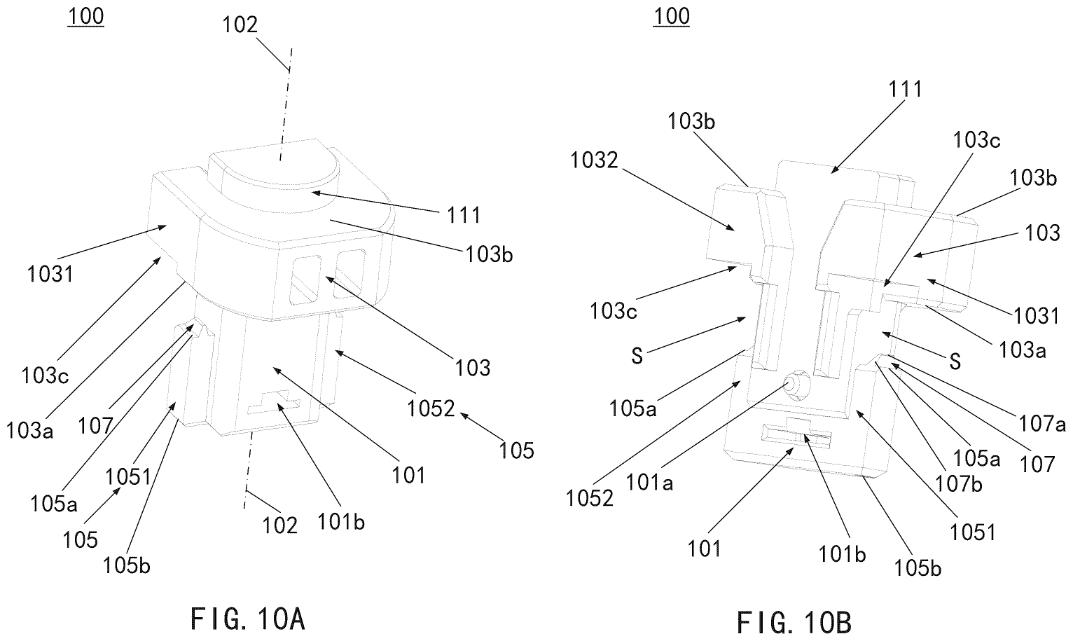

In some examples, as illustrated in FIGS. 9B and 10B, the protrusion 107 may include an engaging surface 107a and a sloped surface 107b. The protrusion 107 may be configured such that, as the first member portion 100 moves from the installing position towards the installed position, the sloped surface 107b may contact the second surface 5b of the second circuit board 5 prior to the engaging surface 107a to guide the engagement of the second surface 5b with the engaging surface 107a of the protrusion 107. By providing the sloped surface 107b, the securement of the member 10 to the second circuit board 5 can be facilitated. It should be appreciated that the sloped surface can be provided both in the case of translation of the first member portion 100 from the installing position to the installed position and in the case of rotation of the first member portion 100 from the installing position to the installed position.

It should be appreciated that although only the second platform 105 is shown in the figures to include the protrusion 107, in some other embodiments, the first platform 103 may also include a protrusion protruding from the first platform surface 103a into the receiving slot S, and the protrusion serves as the first engaging portion to engage with the first surface 5a of the second circuit board 5. Alternatively, only the first platform 103 includes a protrusion protruding from the first platform surface 103a into the receiving slot S, and the protrusion serves as the first engaging portion to engage with the first surface 5a of the second circuit board 5, while the second platform 105 does not include a protrusion. In this case, the second platform surface 105a of the second platform 105 may serve as the second engaging portion to engage with the second surface 5b of the second circuit board 5.

It should also be appreciated that in some other embodiments, both the first platform 103 and the second platform 105 may have no protrusions, and the first platform surface 103a of the first platform 103 serves as the first engaging portion and the second platform surface 105a of the second platform 105 serves as the second engaging portion such that when the first member portion 100 is in the installed position, the first platform surface 103a faces towards and engages with the first surface 5a of the second circuit board 5, and the second platform surface 105a faces towards and engages with the second surface 5b of the second circuit board 5 so as to secure the member 10 to the second circuit board 5. In one of these embodiments, the first platform surface 103a and the second platform surface 105a may face towards each other in the direction of the longitudinal axis 102 such that when the first member portion 100 is in the installed position, the first platform surface 103a and the second platform surface 105a sandwich therebetween a portion of the second circuit board 5 defining the opening 51 to secure the member 10 to the second circuit board 5. In another one of these embodiments, the first platform surface 103a and the second platform surface 105a may be offset from each other in the direction of the longitudinal axis 102. That is, the positive projections of the first platform surface 103a of the first platform 103 and the second platform surface 105a of the second platform 105 in the direction of the longitudinal axis 102 do not overlap with each other. It should be appreciated that in this case, it is also possible to secure the member 10 to the second circuit board 5 by facing and engaging the first platform surface 103a towards and with the first surface 5a of the second circuit board 5 and facing and engaging the second platform surface 105a towards and with the second surface 5b of the second circuit board 5.

In some embodiments, as shown in FIGS. 9A to 10B, the first platform 103 may include a first platform portion 1031 and a second platform portion 1032 protruding from the body 101 opposite to each other, and the second platform 105 may include a third platform portion 1051 and a fourth platform portion 1052 protruding from the body 101 opposite to each other. The first platform portion 1031 and the second platform portion 1032 of the first platform 103 each face a corresponding one of the third platform portion 1051 and the fourth platform portion 1052 of the second platform 105 in the direction of the longitudinal axis 102 such that the first platform portion 1031 and the third platform portion 1051 can sandwich therebetween a first portion of the second circuit board 5 defining the opening 51, and the second platform portion 1032 and the fourth platform portion 1052 can sandwich therebetween a second portion of the second circuit board 5 defining the opening 51, thereby securing the member 10 to the second circuit board 5. In this case, the body 101, the first platform 103 and the second platform 105 of the first member portion 100 may be in a substantially “I-shape”. Such a configuration can improve the reliability of securing the member 10 to the second circuit board 5.

As will be described in detail below, the retaining portion of the member 10 may include a first sub-portion and a second sub-portion. The first sub-portion may be configured to support the third surface 3a of the first circuit board 3 at the first end 31 of the first circuit board 3. The second sub-portion may be configured to be movable between a retained position, in which the second sub-portion engages with the fourth surface 3b of the first circuit board 3 at the first end 31 of the first circuit board 3 such that the first end 31 of the first circuit board 3 is sandwiched between the second sub-portion and the first sub-portion, and a released position, in which the second sub-portion does not engage with the fourth surface 3b of the first circuit board 3.

In some embodiments, as shown in FIGS. 1, 3, and 4, the third platform surface 103b of the first platform 103 may be configured to serve as the first sub-portion to support the third surface 3a of the first circuit board 3 at the first end 31 of the first circuit board 3.

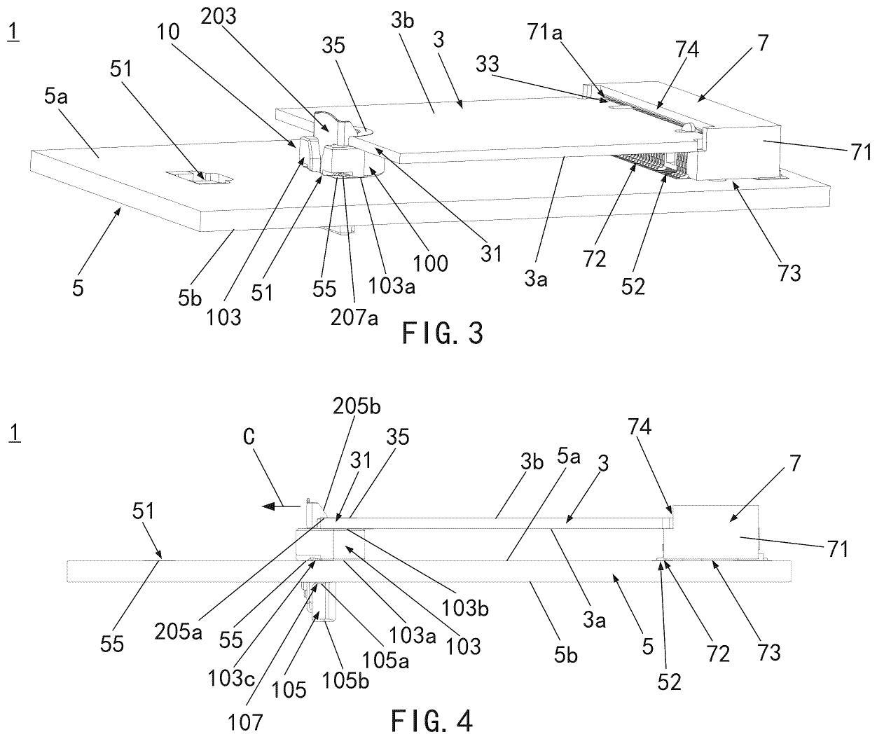

In some embodiments, as shown in FIGS. 1, 3 to 4, and 9A to 9B, the member 10 may include a second member portion 200 mounted on the first member portion 100. The second member portion 200 may include a base 201 secured to the body 101 of the first member portion 100, and a first resilient arm 203 extending from the base 201 in a direction of the longitudinal axis 102 beyond the third platform surface 103b of the first platform 103 of the first member portion 100. The first resilient arm 203 may be configured to serve as the second sub-portion and may be configured to be biased from a retained position (FIG. 1, FIG. 3, and FIG. 4) to a released position (not shown) relative to the third platform surface 103b under the action of a force, and to return from the released position to the retained position under the action of its own resiliency after the force is withdrawn, wherein in the retained position the first resilient arm 203 can engage with the fourth surface 3b of the first circuit board 3 at the first end 31 of the first circuit board 3, and in the released position the first resilient arm 203 does not engage with the fourth surface 3b of the first circuit board 3.

In some embodiments, as shown in FIGS. 9A to 9B, the first resilient arm 203 may include a fixed end 203a connected to the base 201, a free end 203b opposite to the fixed end 203a, and a retention protrusion 205 protruding from the free end 203b and extending to a position above the third platform surface 103b of the first platform 103 of the first member portion 100. Two retention protrusions 205 are illustrated in figures. Each retention protrusion 205 may include an engaging surface 205a. As illustrated in FIG. 4, the engaging surface 205a of the retention protrusion 205 may be configured to engage with the fourth surface 3b of the first circuit board 3 at the first end 31 of the first circuit board 3 when the first resilient arm 203 is in the retained position. It should be appreciated that the first resilient arm 203 may have any other number of retention protrusions, or have a retaining portion in any other suitable form, so as to engage with the fourth surface 3b of the first circuit board 3 at the first end 31 of the first circuit board 3 when the first resilient arm 203 is in the retained position.

In some embodiments, the retention protrusion 205 may further include a sloped surface 205b on a side opposite to the engaging surface 205a. The sloped surface 205b of the retention protrusion 205 may be configured such that the first resilient arm 203 is caused to be biased towards the released position when a force directed in a direction of the longitudinal axis 102 towards the third platform surface 103b acts on the sloped surface 205b. The sloped surface 205b of the retention protrusion 205 may serve as an actuation feature to, when actuated, cause the first resilient arm 203 to be biased from the retained position towards the released position. With such a configuration, for example, in the case where the second end 32 of the first circuit board 3 has been inserted into the electrical connector 7, the first end 31 of the first circuit board 3 may be pressed against the sloped surface 205b of the retention protrusion 205 of the retention protrusion 205 from the side of the sloped surface 205b, causing the first resilient arm 203 to be biased towards the released position, such that the first end 31 of the first circuit board 3 passes over the sloped surface 205b and is received between the engaging surface 205a of the retention protrusion 205 and the third platform surface 103b, thereby being held in position. The sloped surface 205b of the retention protrusion 205 may also be manually actuated by the user.

The retaining protrusion 205 of the first resilient arm 203 may protrude from the first face 2031b of the free end 203b at the free end 203b. In some embodiments, the free end 203b may be configured to cause the first resilient arm 203 to be biased towards the released position when a force directed to the first face 2031b acts on the first face 2031b. For example, as indicated schematically by the arrow C in FIG. 4, the direction of the force may be parallel to the third platform surface 103b. The first face 2031b of the free end 203b may serve as an actuation feature to, when actuated, cause the first resilient arm 203 to be biased from the retained position towards the released position, thereby allowing the first end 31 of the first circuit board 3 to be retained and released. The first face 2031b of the free end 203b can be manually actuated by the user.

With such a configuration, the first end 31 of the first circuit board 3 can be retained and released by the cooperation of the first member portion 100 with the second member portion 200, without additional tools and/or processes. This can facilitate the assembly and disassembly of the first circuit board 3 to and from the second circuit board 5.

It should be appreciated that although the second sub-portion is described in detail above in connection with the form of the resilient arm, the second sub-portion may also be in any other suitable form. For example, the first member portion may also have any other suitable structure, such as a pivotable latch or pin, to serve as the retaining portion. For example, the first member portion and the second member portion may be formed in one piece to provide the mounting portion and the retaining portion.

In some embodiments, the first member portion 100 may further include a positioning post 111 protruding from the body 101 beyond the third platform surface 103b. The positioning post 111 may be configured to cooperate with the notch 34 recessed into the first circuit board 3 from the first end 31 of the first circuit board 3 so as to be received in the notch 34 when the first end 31 of the first circuit board 3 is supported on the third platform surface 103b, to limit the position of the first end 31 of the first circuit board 3. As illustrated in the figures (e.g., FIG. 9A), the positioning post 111 may be a semicircular portion above the platform 103 such that it can fit in the notch that may be a semicircular opening at the edge of the first circuit board 3. This can further enable reliable retention of the first circuit board 3 to the second circuit board 5 to improve the stability of the connection between the first circuit board 3 and the second circuit board 5, and can facilitate assembly of the first circuit board 3 to the second circuit board 5.

In some embodiments, the first member portion 100 of the member 10 may be configured to be electrically insulative and the second member portion 200 may be configured to be electrically conductive. For example, the second member portion 200 may be formed from a conductive material such as a copper or stainless steel. The first member portion 100 may be made from an insulative material. Examples of insulative materials that are suitable for forming the first member portion 100 include, but are not limited to, plastic, nylon, liquid crystal polymer (LCP), polyphenyline sulfide (PPS), high temperature nylon or polyphenylenoxide (PPO) or polypropylene (PP).

As shown in FIGS. 1 to 4, the first circuit board 3 may include a conductive portion 35 (e.g., a conductive pad) disposed on the fourth surface 3b at the first end 31 of the first circuit board 3. As illustrated in FIG. 4, the engaging surface 205a of the retention protrusion 205 of the first resilient arm 203 of the second member portion 200 may be configured to engage and establish an electrical contact with the conductive portion 35 of the first circuit board 3 when the first resilient arm 203 is in the retained position. The conductive portion 35 of the first circuit board 3 may be coupled to a ground plane of the first circuit board 3. It should be appreciated that a ground plane needs not be connected to earth ground, but carries a reference potential, which may include earth ground, DC voltage or other suitable reference potential.

As shown in FIGS. 1 to 4, the second circuit board 5 may include a conductive portion 55 (e.g., a conductive pad) disposed adjacent to the opening 51 on the first surface 5a of the second circuit board 5. As illustrated in FIG. 4, the second member portion 200 may include a second resilient arm 207 extending from the base 201 to a position between the first platform 103 and the second platform 105. Two second resilient arms 207 are illustrated in the figures. Each second resilient arm 207 may be configured to resiliently abut against the conductive portion 55 of the second circuit board 5 when the first member portion 100 is in the installed position so as to establish an electrical contact with the conductive portion 55. It should be appreciated that the second member portion 200 may include any other suitable number of second resilient arms. The conductive portion 55 of the second circuit board 5 may be coupled to a ground plane of the second circuit board 5.

In this way, it is possible to electrically connect the conductive portion 35 of the first circuit board 3 with the conductive portion 55 of the second circuit board 5 via the second member portion 200. This can, for example, provide a ground path between the first circuit board 3 and the second circuit board 5, which can reduce electromagnetic interference (EMI).

In some embodiments, as shown in FIGS. 4, 9A, and 9B, the first platform surface 103a of the first platform 103 serves as the first engaging portion such that the first platform surface 103a faces towards and engages with the first surface 5a of the second circuit board 5 when the first member portion 100 is in the installed position. The first platform 103 may include a recess 103c recessed into the first platform 103 from the first platform surface 103a along the direction of the longitudinal axis 102. As illustrated in FIGS. 9A and 9B, the second resilient arm 207 may include a fixed end connected to the base 201 and a free end opposite to the fixed end. The free end of the second resilient arm 207 is received in the recess 103c, and the end portion 207a of the free end protrudes from the first platform surface 103a such that the free end can resiliently abut against the conductive portion 55 of the second circuit board 5 to establish an electrical contact with the conductive portion 55 when the first member portion 100 is in the installed position.

In some other embodiments, the first member portion 100 and the second member portion 200 of the member 10 may be formed from any other suitable material. For example, the first member portion 100 and the second member portion 200 may both be formed from an insulative material, or may both be formed from an electrically conductive material.

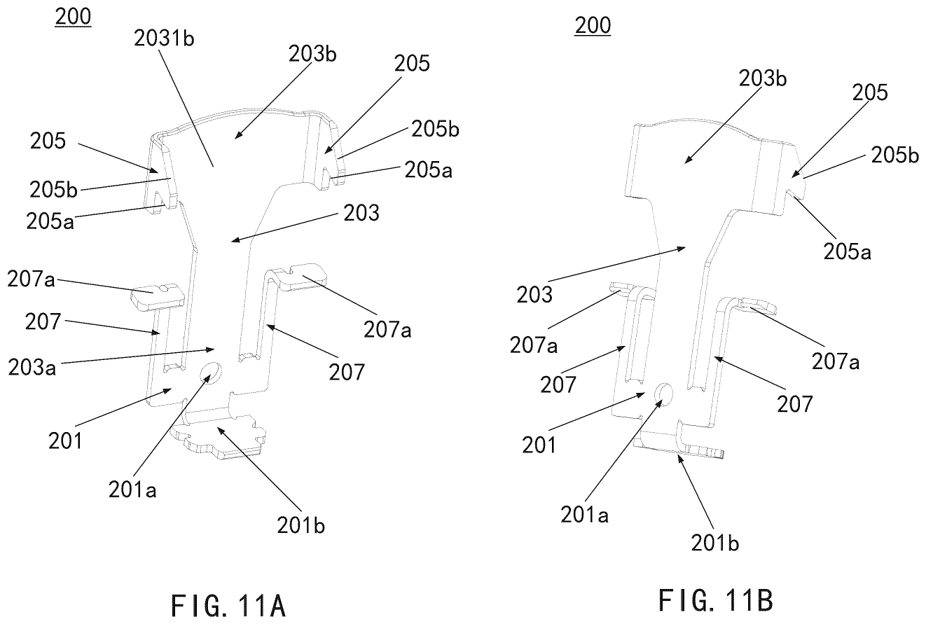

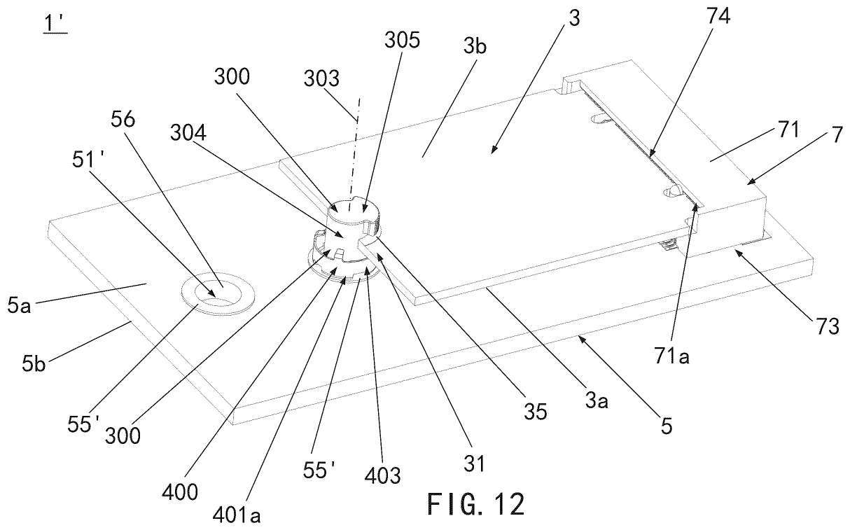

In some embodiments, as shown in FIGS. 9B, 10A to 10B, and 11A to 11B, the body 101 of the first member portion 100 may include a post 101a, and the base 201 of the second member portion 200 may include an aperture 201a. The base 201 of the second member portion 200 may be mounted to the body 101 of the first member portion 100 by cooperating the aperture 201a with the post 101a to extend the post 101a through the aperture 201a. Alternatively or additionally, as shown in FIGS. 9B and 11A to 11B, the base 201 may include a mounting arm 201b, on which a barb feature may be formed. For example, the mounting arm 201b may extend oppositely to the first resilient arm 203. As shown in FIGS. 9A to 9B and 10A to 10B, the body 101 of the first member portion 100 may include a slot 101b recessed into the body 101. The base 201 of the second member portion 200 may be mounted to the body 101 of the first member portion 100 by inserting the mounting arm 201b of the base 201 into the slot 101b of the body 101 of the first member portion 100. It should be appreciated that the present application is not limited thereto, and that the base 201 of the second member portion 200 may be mounted to the body 101 of the first member portion 100 in any other suitable manner.

The present application also proposes a method of operating the member 10 described above. The method includes: cooperating the mounting portion of the member 10 with the opening 51 of the second circuit board 5 to secure the member 10 to the second circuit board 5; placing the retaining portion of the member 10 in the released position and disposing the first circuit board 3 on the retaining portion; and moving the retaining portion from the released position to the retained position to retain the first end 31 of the first circuit board 3 in place relative to the second circuit board 5.

In some embodiments, cooperating the mounting portion of the member 10 with the opening 51 of the second circuit board 5 includes engaging the first engaging portion of the mounting portion with the first surface 5a of the second circuit board 5, and engaging the second engaging portion of the mounting portion with the second surface 5b of the second circuit board 5 to secure the member 10 to the second circuit board 5.

In some embodiments, cooperating the mounting portion of the member 10 with the opening 51 of the second circuit board 5 includes inserting the first member portion 100 into the opening 51 such that the first platform 103 and the second platform 105 are positioned on the two opposite sides of the second circuit board 5, respectively.

In some embodiments, cooperating the mounting portion of the member 10 with the opening 51 of the second circuit board 5 includes inserting the first member portion 100 of the member 10 into the opening 51 in the insertion orientation, in which the longitudinal axis 102 is substantially perpendicular to the first surface 5a of the second circuit board 5, to the installing position shown in FIGS. 5 to 6, and moving the first member portion 100 from the installing position, in which the first platform 103 and the second platform 105 are positioned on the two opposite sides of the second circuit board 5, respectively, to the installed position shown in FIGS. 3 to 4 and 7 to 8, in which the first engaging portion engages with the first surface 5a of the second circuit board 5 and the second engaging portion engages with the second surface 5b of the second circuit board 5.

In some embodiments, inserting the first member portion 100 into the opening 51 in the insertion orientation to the installing position includes inserting the first member portion 100 into the first opening portion 51a of the opening 51 in the insertion orientation such that the first platform 103 and the second platform 105 are positioned on the two opposite sides of the second circuit board 5, respectively.

In some embodiments, moving the first member portion 100 from the installing position to the installed position includes translating the first member portion 100 from the installing position in the direction substantially parallel to the first surface 5a into the second opening portion 51b of the opening 51 communicating with the first opening portion 51a.

In some embodiments, moving the first member portion 100 from the installing position to the installed position includes rotating the first member portion 100 from the installing position to the installed position about the longitudinal axis 102 or about an axis parallel to the longitudinal axis 102.

In some embodiments, placing the retaining portion in the released position includes placing the second sub-portion of the retaining portion in the releasing position in which the second sub-portion does not engage with the fourth surface 3b of the first circuit board 3, and disposing the first circuit board 3 on the retaining portion includes supporting the third surface 3a of the first circuit board 3 opposite to the fourth surface 3b at the first end 31 of the first circuit board 3 with the first sub-portion of the retaining portion.

In some embodiments, cooperating the mounting portion of the member 10 with the opening 51 of the second circuit board 5 includes inserting the first member portion 100 into the opening 51 such that the first platform 103 surface faces towards and engages with the first surface 5a of the second circuit board 5, and disposing the first circuit board 3 on the retaining portion includes supporting the third surface 3a of the first circuit board 3 at the first end 31 of the first circuit board 3 with the third platform surface 103b.

In some embodiments, placing the second sub-portion of the retaining portion in the releasing position includes applying a biasing force to bias the first resilient arm 203 to the releasing position.

In some embodiments, biasing the first resilient arm 203 to the releasing position includes pressing the first end 31 of the first circuit board 3 against the sloped surface 205b from the side of the sloped surface 205b of the retention protrusion 205 to bias the first resilient arm 203 to the releasing position.

In some embodiments, moving the retaining portion from the released position to the retained position includes withdrawing the biasing force to return the first resilient arm 203 to the retained position to engage the engaging surface 205a of the retention protrusion 205 with the conductive portion 35.

In some embodiments, moving the first member portion 100 from the installing position to the installed position includes resiliently abutting the second resilient arm 207 against the conductive portion 55.

It should be appreciated that the above are only some examples of the method of operating the aforementioned member 10, and that the present application is not limited thereto.

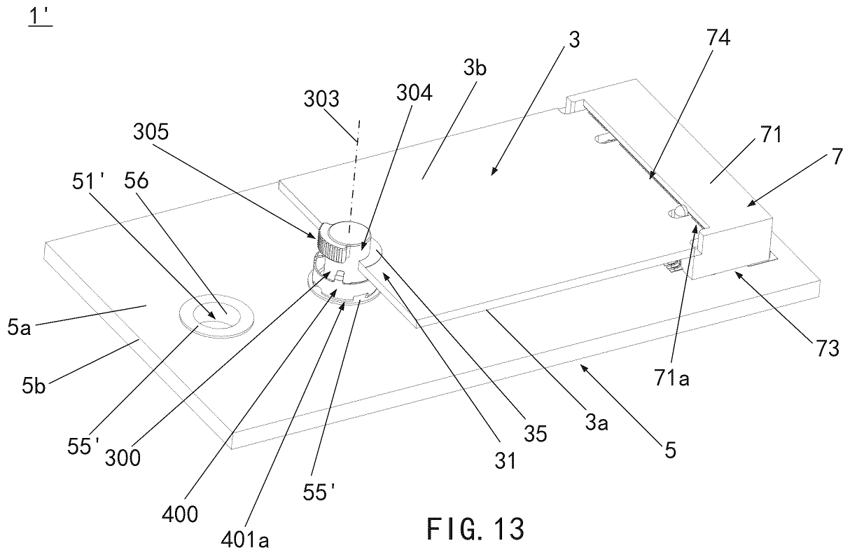

FIGS. 12 to 18D schematically illustrate an electronic system 1′ according to another embodiment of the present application. Similar to the electronic system 1 shown in FIGS. 1 to 11B, the electronic system 1′ shown in FIGS. 12 to 18D may also include a first circuit board, a second circuit board, an electrical connector, and a member 40, wherein the first circuit board, the second circuit board, and the electrical connector shown in FIGS. 12 to 15 are substantially the same as the first circuit board 3, the second circuit board 5, and the electrical connector 7 shown in FIGS. 1 to 8, respectively. Accordingly, the same reference numbers are used in FIGS. 12 to 15 to indicate the portions of the first circuit board, the second circuit board and the electrical connector that are identical to those of the first circuit board 3, the second circuit board 5 and the electrical connector 7 shown in FIGS. 1 to 8, and such identical portions are not described repeatedly herein.

As shown in FIGS. 12 to 15, the electronic system 1′ may include the first circuit board 3, the second circuit board 5, the electrical connector 7 and the member 40. The second circuit board 5 shown in FIGS. 12 to 15 differs from the second circuit board 5 shown in FIGS. 1 to 8 in that the opening (identified with the reference number “51”′ in FIGS. 12 to 15) of the second circuit board 5 of the electronic system 1′ has a different shape from that of the opening 51 of the second circuit board 5 of the electronic system 1. The opening 51′ of the second circuit board 5 of the electronic system 1′ extends from the first surface 5a through the first circuit board 3 to the second surface 5b opposite to the first surface 5a.

Similar to the member 10 shown in FIGS. 1 to 11B, the member 40 of the electronic system 1′ may be configured for retaining and releasing the first circuit board 3 to and from the second circuit board 5. As will be described in detail below, the member 40 may include a mounting portion and a retaining portion. The mounting portion may be configured to cooperate with the opening 51′ of the second circuit board 5 to secure the member 40 to the second circuit board 5. The retaining portion may be configured to be movable between a retained position, in which the retaining portion retains the first end 31 of the first circuit board 3 in place relative to the second circuit board 5, and a released position, in which the retaining portion releases the first end 31 of the first circuit board 3 from the second circuit board 5, when the member 40 is secured to the second circuit board 5. The member 40 can help to reliably retain the first circuit board 3 to the second circuit board 5 to improve the stability of the connection between the first circuit board 3 and the second circuit board 5, and can facilitate the assembly and disassembly of the first circuit board 3 to and from the second circuit board 5.

In some embodiments, as will be described in detail below, the mounting portion may be configured to resiliently abut against a boundary of the opening 51′ in the opening 51′ of the second circuit board 5 to secure the member 40 to the second circuit board 5. That is, the mounting portion may be configured to resiliently abut against a portion of the second circuit board 5 defining the opening 51′ in the opening 51′ of the second circuit board 5 to secure the member 40 to the second circuit board 5.

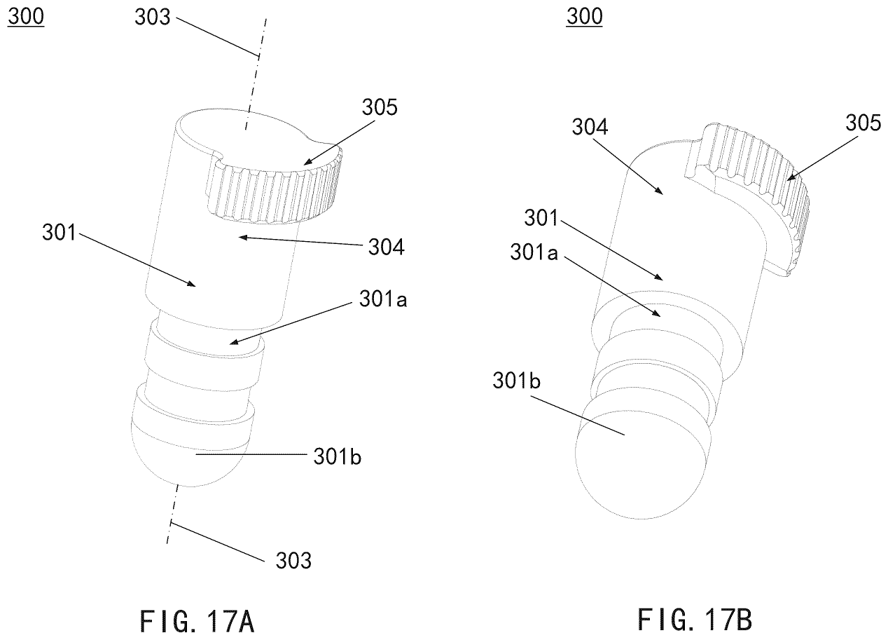

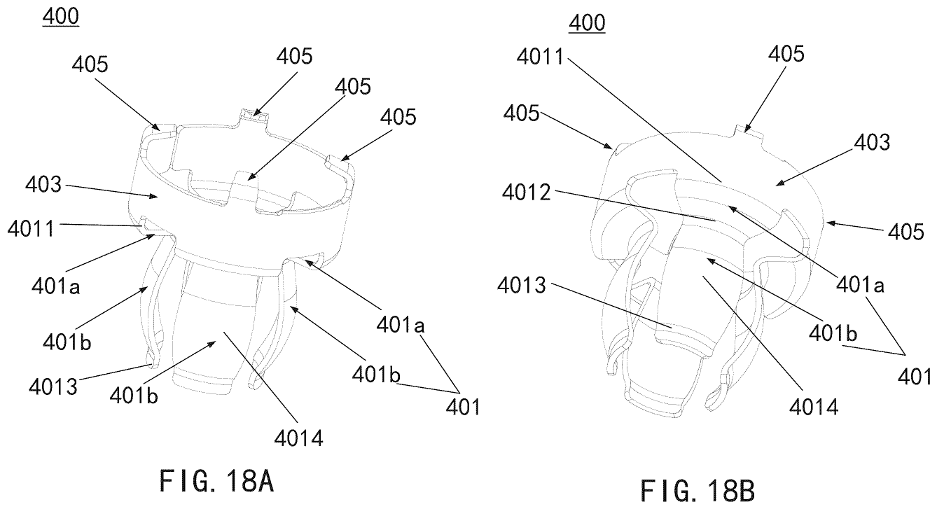

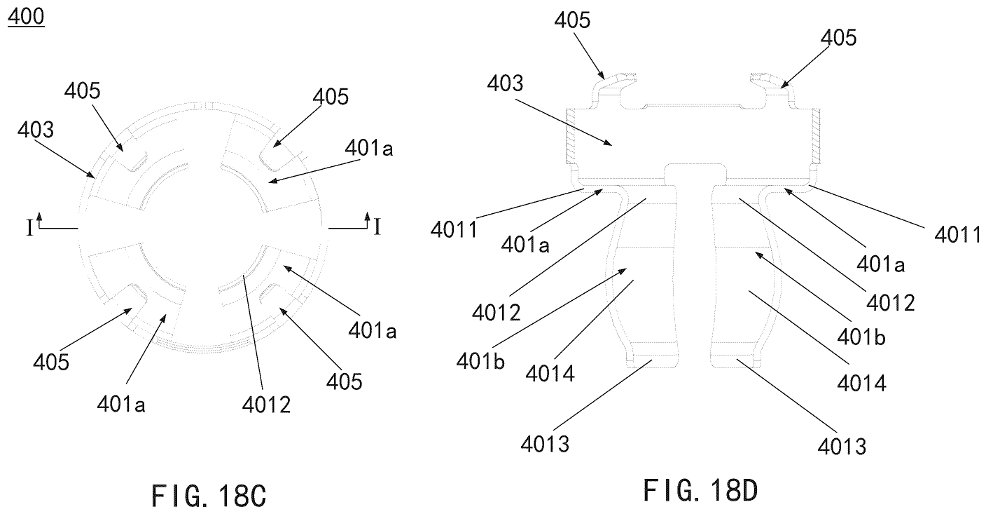

In one of these embodiments, as shown in FIGS. 12 to 18D, the member 40 may include a first member portion 300 (FIGS. 17A and 17B) and a second member portion 400 (FIGS. 18A to 18D) mounted on the first member portion 300. The first member portion 300 may include an insert portion 301 extending along a longitudinal axis 303. The second member portion 400 may include a plurality of first resilient arms 401 disposed on the insert portion 301. The plurality of first resilient arms 401 may be configured to serve as the mounting portion. The insert portion 301 of the first member portion 300 and the plurality of first resilient arms 401 of the second member portion 400 may be configured to be inserted into the opening 51′ of the second circuit board 5 such that the plurality of first resilient arms 401 resiliently abut against the boundary of the opening 51′ of the second circuit board 5, thereby securing the member 40 to the second circuit board 5. Four first resilient arms 401 are shown in the figures. It should be appreciated that the second member portion 400 may include any other suitable number of first resilient arms, such as two, three or more than four first resilient arms, and the present application is not limited thereto. The insert portion 301 and the plurality of first resilient arms 401 may be configured to be inserted into the opening 51′ from the first surface 5a and/or the second surface 5b of the second circuit board 5 in an insertion orientation in which the longitudinal axis 303 is substantially perpendicular to the first surface 5a of the second circuit board 5.

With such a configuration, the member 40 can be secured to and removed from the second circuit board 5 without additional tools and/or processes. Compared to fixing to the circuit board with additional tools required by such as screws and/or additional processes such as soldering, the structure of the present application facilitates mounting and removal and enables reusability. The member 40 can be easily removed from one opening 51′ of the second circuit board 5 and subsequently easily installed into another opening 51′ of the second circuit board 5, thereby facilitating cooperating with first circuit boards 3 of different lengths.

As shown in FIGS. 12 to 18D, the second member portion 400 may further include a body 403 connecting the plurality of first resilient arms 401. Each of the plurality of first resilient arms 401 may include a first portion 401a extending from the body 403 and a second portion 401b extending from the first portion 401a. The first portion 401a may include a first end 4011 and a second end 4012 opposite to the first end 4011. The first portion 401a may be connected to the body 403 at the first end 4011 and to the second portion 401b at the second end 4012. The second portion 401b may extend from the second end 4012 of the first portion 401a, and may include a third end 4013 opposite to the second end 4012.

In some embodiments, the body 403 of the second member portion 400 may be annular and disposed around the insert portion 301. In some embodiments, the plurality of first resilient arms 401 of the second member portion 400 are arranged to be rotationally symmetrical about the longitudinal axis 303 of the first member portion 300.

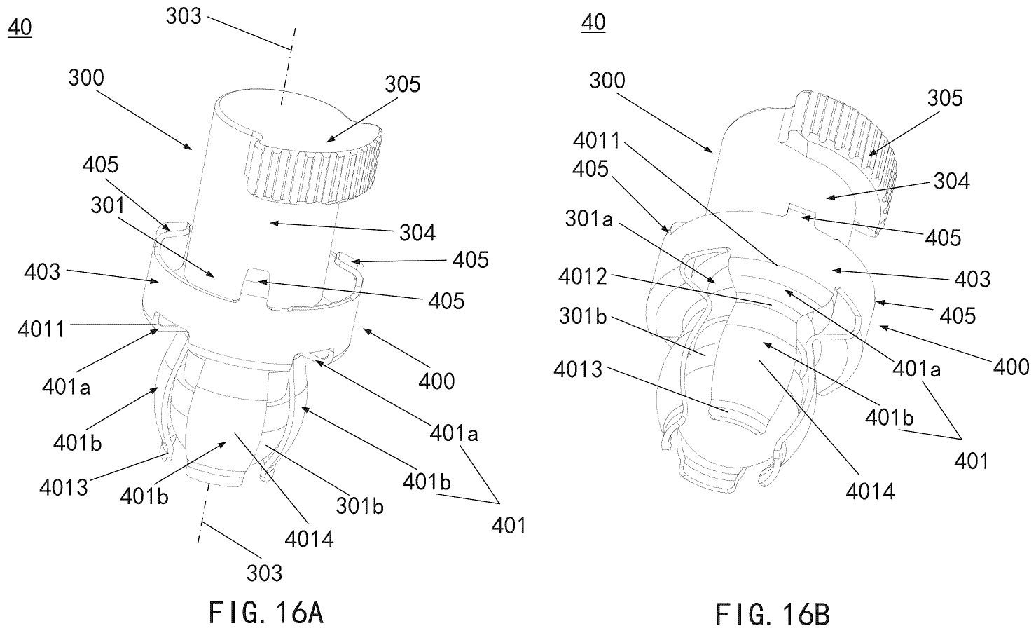

The first portion 401a may be configured to extend towards the insert portion 301 in a direction substantially perpendicular to the longitudinal axis 303 and engage with the insert portion 301 to retain the body 403 on the first member portion 300. In some embodiments, the insert portion 301 may include an outer surface 301b and a groove 301a recessed into the insert portion 301 from the outer surface 301b in a direction substantially parallel to the longitudinal axis 303. FIGS. 16A to 16B illustrate the insert portion 301 of the first member portion 300 of the member 40 initially inserted into the body 403 of the second member portion 400, such that the insert portion 301 is surrounded by the annular body 403 and the plurality of first resilient arms 401. The first member portion 300 and the second member portion 400 of the member 40 may further be cooperated relative to the state shown in FIGS. 16A to 16B such that the second ends 4012 of the first portions 401a of the plurality of first resilient arms 401 are received in the groove 301a of the insert portion 301 to retain the body 403 on the first member portion 300.

The second portion 401b may be configured to extend from the first portion 401a in a direction substantially parallel to the longitudinal axis 303 and bend convexly and outwardly away from the insert portion 301. The second portion 401b may be configured to engage with the boundary of the opening 51′ of the second circuit board 5. The intermediate portion 4014 of the second portion 401b between the second end 4012 and the third end 4013 is bent outwardly and convexly away from the insert portion 301 to engage with the boundary of the opening 51′. When the intermediate portion 4014 of the second portion 401b is biased inwardly towards the insert portion 301, the second end 4012 of the first portion 401a can engage with the wall of the groove, and the third end 4013 of the second portion 401b can engage with the outer surface 301b of the insert portion 301 to provide support to the intermediate portion against biasing. This enables the intermediate portion 4014 of the second portion 401b to abut firmly against the boundary of the opening 51′ of the second circuit board 5 when the insert portion 301 of the first member portion 300 and the plurality of first resilient arms 401 of the second member portion 400 are inserted in the opening 51′ of the second circuit board 5. For example, the second ends 4012 of the first portions 401a can engage with the side wall or bottom wall of the recess.

In some embodiments, the first portion 401a may also be configured to interfere with the first surface 5a of the second circuit board 5 as the insert portion 301 and the plurality of first resilient arms 401 are inserted from the first surface 5a of the second circuit board 5 into the opening 51′ to limit further insertion of the insert portion 301 and the plurality of first resilient arms 401 into the opening 51′ when the second portion 401b is inserted into the opening 51′. In this way, a unidirectional insertion of the member 40 can be achieved to prevent the member 40 from being inserted into the opening 51′ in an improper orientation.

As will be described in detail below, the retaining portion of the member 40 may have a first sub-portion and a second sub-portion. The first sub-portion may be configured to support the third surface 3a of the first circuit board 3 at the first end 31 of the first circuit board 3. The second sub-portion may be configured to be movable between a retained position, in which the second sub-portion engages with the fourth surface 3b of the first circuit board 3 opposite to the third surface 3a at the first end 31 of the first circuit board 3 such that the first end 31 of the circuit board 3 is sandwiched between the second sub-portion and the first sub-portion, and a released position, in which the second sub-portion does not engage with the fourth surface 3b of the first circuit board 3. As described above, the third surface 3a and the fourth surface 3b of the second circuit board 5 are opposite to each other and substantially parallel to each other.

In some embodiments, as shown in FIGS. 16A to 16B, 18A to 18B, and 18D, the second member portion 400 may include a plurality of second resilient arms 405 extending from the body 403 on the side of the body 403 opposite to the plurality of first resilient arms 401. Four second resilient arms 405 are shown in the figures. It should be appreciated that the second member portion 400 may include any other suitable number of second resilient arms, such as two, three, or more than four second resilient arms, and the present application is not limited thereto. The plurality of second resilient arms 405 may serve as the first sub-portion to support the third surface 3a of the first circuit board 3. Alternatively or additionally, the second member portion 400 may include any other forms of first sub-portion, such as one or platforms, a continuous annular portion, etc. That is, the second member portion 400 may include a portion on the side of the body 403 opposite to the plurality of first resilient arms 401, and the portion is configured to serve as the first sub-portion to support the third surface 3a of the first circuit board 3.

In some embodiments, the first member portion 300 may include a sub-portion. In one of these embodiments, as shown in FIGS. 16A to 17B, the sub-portion may include a body 304 extending from the insert portion 301 in the direction of the longitudinal axis 303 beyond the first sub-portion of the second member portion 400 (the first sub-portion is illustrated in the drawings as the second resilient arms 405), and a protrusion 305 protruding from the body 304, the protrusion 305 may be configured to serve as the second sub-portion. The first member portion 300 and the second member portion 400 may be configured such that at least the first member portion 300 is rotatable in the opening 51′ of the second circuit board 5 when the insert portion 301 and the plurality of first resilient arms 401 are inserted in the opening 51′, thereby enabling the protrusion 305 to move between a retained position, in which the protrusion 305 may be adjacent and/or engage with the fourth surface 3b of the first circuit board 3 at the first end 31 of the first circuit board 3 such that the first end 31 of the first circuit board 3 is sandwiched between the protrusion 305 and the first sub-portion (e.g., at least one of the plurality of second resilient arms 405), and a released position, in which the protrusion 305 does not engage with the fourth surface 3b of the first circuit board 3. The body 304 and/or the protrusions 305 may be configured to be manually actuated by the user.

With such a configuration, the first end 31 of the first circuit board 3 can be retained and released by the cooperation of the first member portion 300 with the second member portion 400 without additional tools and/or processes. This can facilitate the assembly and disassembly of the first circuit board 3 to and from the second circuit board 5.

It should be appreciated that in some other embodiments, the sub-portion of the first member portion 300 may include a second sub-portion in any suitable form, such as the first resilient arm 203 described in connection with FIGS. 1 to 4.

In some embodiments, the first member portion 300 of the member 40 may be configured to be electrically insulative, and the second member portion 400 may be configured to be electrically conductive. For example, the second member portion 400 may be formed from a conductive material such as a copper or stainless steel. The first member portion 300 may be made from an insulative material. Examples of insulative materials that are suitable for forming the first member portion 300 include, but are not limited to, plastic, nylon, liquid crystal polymer (LCP), polyphenyline sulfide (PPS), high temperature nylon or polyphenylenoxide (PPO) or polypropylene (PP).

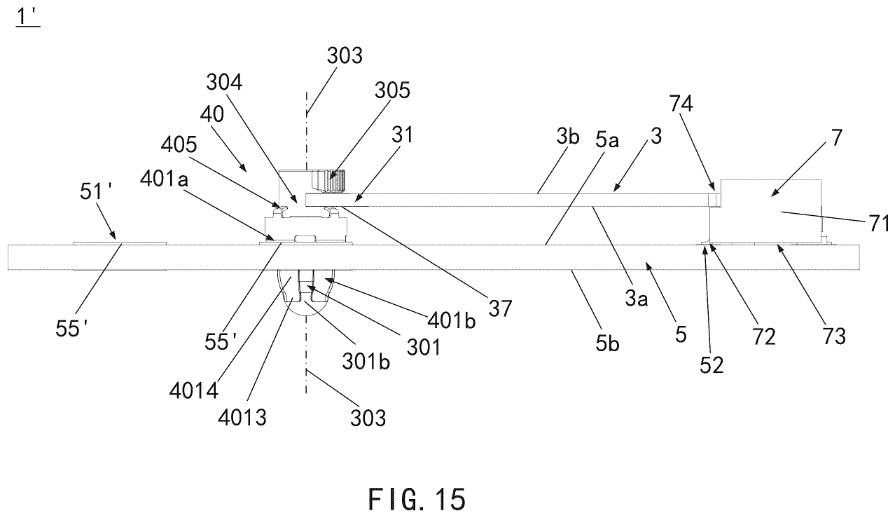

As shown in FIG. 15, the first circuit board 3 may include a conductive portion 37 (e.g., a conductive pad) disposed on the third surface 3a at the first end 31 of the first circuit board 3. The first sub-portion of the second member portion 400 (the first sub-portion is illustrated in the drawings as the second resilient arms 405) can engage with the conductive portion 37 and establish an electrical contact with the conductive portion 37 when the first sub-portion supports the third surface 3a of the first circuit board 3. The conductive portion 37 of the first circuit board 3 may be coupled to a ground plane of the first circuit board 3.

As shown in FIGS. 12 to 15, the second circuit board 5 may include a conductive portion 55′ (e.g., a conductive pad) disposed adjacent to the opening 51′ on the first surface 5a of the second circuit board 5. In the case where the insert portion 301 and the plurality of first resilient arms 401 can be inserted into the opening 51′ from the first surface 5a of the second circuit board 5, when the insert portion 301 and the first resilient arms 401 are inserted into the opening 51′ to secure the member 40 to the second circuit board 5, the insert portion 301 can press against a portion of the first portion 401a between the first end 4011 and the second end 4012, such that the portion of the first portion 401a is pressed against the conductive portion 55′ of the second circuit board 5 and establish an electrical contact with the conductive portion 55′. The conductive portion 55′ of the second circuit board 5 may be coupled to a ground plane of the second circuit board 5. In this way, it is possible to electrically connect the conductive portion 37 of the first circuit board 3 to the conductive portion 55′ of the second circuit board 5 via the second member portion 200. This can, for example, provide a ground path between the first circuit board 3 and the second circuit board 5, which can reduce EMI.

In some embodiments, the first circuit board 3 may include a conductive portion 56 disposed in the opening 51′ on the boundary of the opening 51′. When the plurality of first resilient arms 401 are inserted into the opening 51′, the second portions 401b engage with the conductive portion 56 of the first circuit board 3 and establish an electrical contact with the conductive portion 56. In this way, it is possible to electrically connect the conductive portion 37 of the first circuit board 3 to the conductive portion 56 of the second circuit board 5 via the second member portion 200. This can, for example, provide a ground path between the first circuit board 3 and the second circuit board 5.

In some other embodiments, the first member portion 300 and the second member portion 400 of the member 40 may be formed from any other suitable material. For example, the first member portion 300 and the second member portion 400 can both be formed from insulative material, or both formed from conductive material.

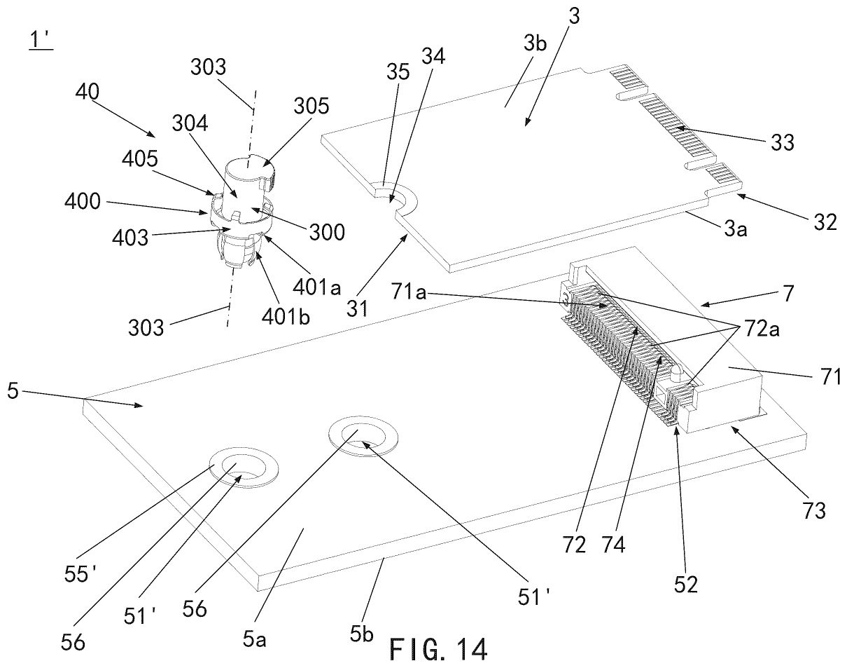

In some embodiments, as shown in FIG. 14, the body 304 of the sub-portion may be configured to cooperate with the notch 34 recessed into the first circuit board 3 from the first end 31 of the first circuit board 3 such that the body 304 is received in the notch 34 of the first circuit board 3 when the first end 31 of the first circuit board 3 is supported on the first sub-portion (e.g., the second resilient arms 405), to limit the position of the first end 31 of the first circuit board 3. This can further enable reliable retention of the first circuit board 3 to the second circuit board 5 to improve the stability of the connection between the first circuit board 3 and the second circuit board 5, and can facilitate assembly of the first circuit board 3 to the second circuit board 5.

It should be appreciated that the mounting portion may be configured in any suitable manner. For example, the mounting portion can be manufactured from an elastic material and/or include an elastic portion.

It should be appreciated that although the second sub-portion is described above in connection with the form of resilient arms, the second sub-portion may be in any other suitable form. As an example, the first member portion may also have any other suitable forms of structure thereon to serve as the retaining portion. As another example, the first member portion and the second member portion may be formed in one piece to provide the mounting portion and the retaining portion.

The present application also proposes a method of operating the aforementioned member 40. The method includes: cooperating the mounting portion of the member 40 with the opening 51′ of the second circuit board 5 to secure the member 40 to the second circuit board 5; placing the retaining portion of the member 40 in the released position and disposing the first circuit board 3 on the retaining portion; and moving the retaining portion from the released position to the retained position to retain the first end 31 of the first circuit board 3 in place relative to the second circuit board 5.

In some embodiments, cooperating the mounting portion of the member 40 with the opening 51′ of the second circuit board 5 includes resiliently abutting the mounting portion against the boundary of the opening 51′ in the opening 51′ of the second circuit board 5.

In some embodiments, cooperating the mounting portion of the member 40 with the opening 51′ of the second circuit board 5 includes inserting the insert portion 301 of the first member portion 300 and the plurality of first resilient arms 401 of the second member portion 400 into the opening 51′ of the second circuit board 5 such that the plurality of first resilient arms 401 resiliently abut against the boundary of the opening 51′.

In some embodiments, placing the retaining portion in the released position includes placing the second sub-portion of the retaining portion in the releasing position, in which the second sub-portion does not engage with the fourth surface 3b of the first circuit board 3, and disposing the first circuit board 3 on the retaining portion includes supporting the third surface 3a of the first circuit board 3 opposite to the fourth surface 3b at the first end 31 of the first circuit board 3 with the first sub-portion of the retaining portion.

In some embodiments, moving the retaining portion from the released position to the retained position includes rotating the first member portion 100 in the opening 51′ of the second circuit board 5 to cause the protrusion 305 to move to the retained position.

In some embodiments, disposing the first circuit board 3 on the retaining portion comprises engaging the first sub-portion with the conductive portion 35 of the first circuit board 3 and establishing an electrical contact with the conductive portion 35.

In some embodiments, cooperating the mounting portion of the member 40 with the opening 51′ of the second circuit board 5 includes inserting the insert portion 301 and the plurality of first resilient arms 401 into the opening 51′ such that the insert portion 301 presses against a portion of the first portion 401a between the first end 4011 and the second end 4012 such that the portion of the first portion 401a is pressed against the conductive portion 55′ of the second circuit board 5 and establishes an electrical contact with the conductive portion 55′.

It should be appreciated that the above are only some examples of methods of operating the aforementioned member 40, and that the present application is not limited thereto.

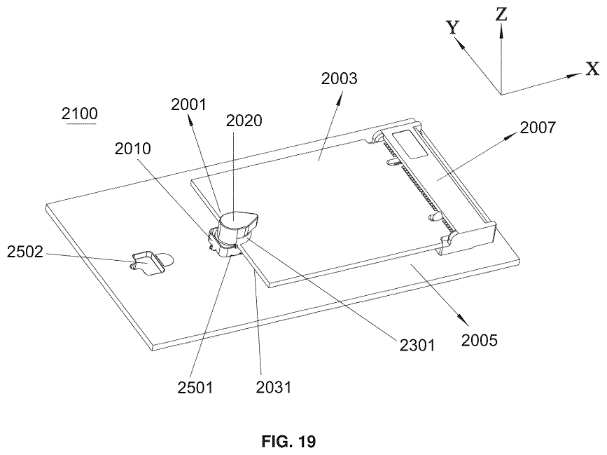

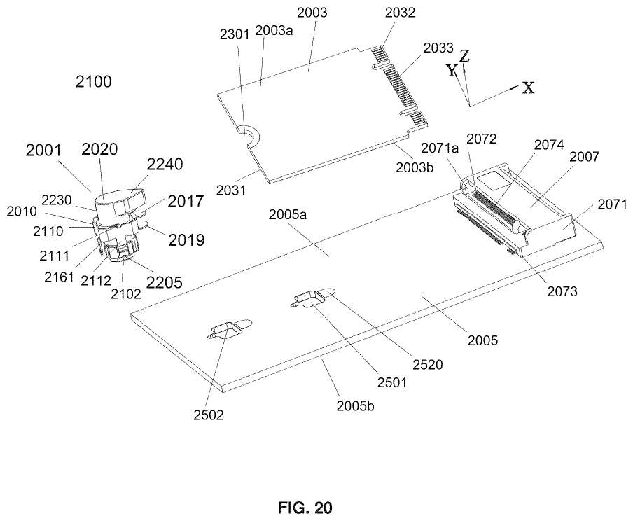

Another exemplary embodiment of the electronic system and the member will be described with reference to FIGS. 19-32. A transverse direction Y, a horizontal direction X and a vertical direction Z are labeled in some of the FIGS. 19-32. The transverse direction Y, the horizontal direction X and the vertical direction Z may be perpendicular to one another. The vertical direction Z may refer to an insertion direction that the member is inserted through the first and second printed circuit boards. The horizontal direction X may refer to a longitudinal direction of the first or second printed circuit board.

It is to be understood that orientation or positional relations indicated by terms such as “vertical”, “horizontal”, “inside”, “outside”, “front”, and “rear” are based on the orientation or positional relations as shown in the figures, for facilitating description of the present application and simplifying the description, rather than indicating or implying that the referred devices or elements must be in a particular orientation or constructed or operated in the particular orientation, and therefore they should not be construed as limiting the present application.

The member according to an exemplary embodiment of the present application may be used to retain and release a subassembly to and from the electronic system without the need for additional tools and/or processes. The subassembly (which may sometimes be referred to as the first printed circuit board) may comprise add-in cards for various functions, such as Solid-state drive (SSD) cards, wireless communication cards, radio frequency modules, etc. One end of the add-in card may be inserted into an electrical connector mounted on a second printed circuit board (such as a motherboard), and the other end of the add-in card is at a distal end side of the electrical connector. The technical aspects described here may allow for the retention and release of various sizes of add-in cards without the need for additional tools and/or processes.

FIGS. 19 to 24 schematically illustrate an electronic system 2100 according to some exemplary embodiments of the present application. As shown in FIGS. 19 to 24, the electronic system 2100 comprises a first printed circuit board 2003, a second printed circuit board 2005, an electrical connector 2007, and a member 2001.

The first printed circuit board 2003 may also be referred to as a “first printed circuit board” or a “first PCB”, and for example, it may be a sub-card or an add-in card such as a Solid-state drive (SSD) card, a wireless communication card, a radio frequency module, etc. As shown in FIGS. 19 and 20, the first printed circuit board 2003 may comprise a first end 2031, a second end 2032 opposite to the first end 2031, an upper surface 2003a, and a lower surface 2003b. The upper surface 2003a and the lower surface 2003b may be opposite and substantially parallel to each other. The first printed circuit board 2003 may further comprise an electrically conductive portion (such as an electrically conductive pad) 2033 provided at or near an edge of the first printed circuit board 2003 at the second end 2032, and may comprise a notch 2301 provided approximately at a central portion of the first end 2031. The notch 2301 may extend from the upper surface 2003a through the first printed circuit board 2003 to the lower surface 2003b.

The second printed circuit board 2005 may also be referred to as a “second PCB”, and for example, it may be a motherboard. As shown in FIG. 20, the second printed circuit board 2005 may comprise an upper surface 2005a, and a lower surface 2005b. The upper surface 2005a and the lower surface 2005b may be opposite and substantially parallel to each other. The second printed circuit board 2005 may further comprise an electrically conductive portion provided on the upper surface 2005a. The electrically conductive portion may be, for example, an electrically conductive pad or an electrically conductive through-hole. As will be specifically described in the following text, the electrically conductive portion is configured to be connected to an electrical connector 2007. The second printed circuit board 2005 may further comprise at least one opening 2501.

Two openings 2501 and 2502 are shown in FIGS. 19 and 20. It should be understood that the opening may be in the number of one, and two or more openings may be provided, where the plurality of openings may have the same structure, but at different distances from the electrical connector. As will be specifically described in the following text, providing the second printed circuit board 2005 with a plurality of openings may enable the second printed circuit board 2005 to cooperate with sub-cards of different lengths. Each opening 2501 may extend from the upper surface 2005a through the second printed circuit board 2005 to the lower surface 2005b. That is, each opening 2501 extends through the second printed circuit board 2005.

The electrical connector 2007 may be configured to connect the first printed circuit board 2003 with the second printed circuit board 2005 to achieve a signal and/or power transmission between the first printed circuit board 2003 and the second printed circuit board 2005. As shown in FIGS. 19 and 20, the first printed circuit board 2003 and the second printed circuit board 2005 are configured to be oriented in a direction substantially parallel to each other, so that the upper surface 2005a of the second printed circuit board 2005 is facing and substantially parallel to the lower surface 2003b of the first printed circuit board 2003, and so that the lower surface 2005b of the second printed circuit board 2005 is facing away from and substantially parallel to the upper surface 2003a of the first printed circuit board 2003.

As shown in FIG. 20, the electrical connector 2007 may comprise a housing 2071, a plurality of electrically conductive terminals 2072 provided in the housing 2071, a mounting engagement portion 2073, and a cooperation engagement portion 2074. The electrical connector 2007 may be configured to be mounted on the upper surface 2005a of the second printed circuit board 2005 at the mounting engagement portion 2073, so that the plurality of electrically conductive terminals 2072 establish an electrical connection with the electrically conductive portion on the upper surface 2005a at the mounting engagement portion 2073. For example, when the electrically conductive portion of the second printed circuit board 2005 is an electrically conductive pad, a plurality of electrically conductive terminals 2072 may be soldered on the electrically conductive pad through the Surface-mount technology. In addition, when the electrically conductive portion of the second printed circuit board 2005 is an electrically conductive through hole, the plurality of electrically conductive terminals 2072 may be pressed and fitted in the electrically conductive through hole.

The electrical connector 2007 may also be configured to cooperate with the first printed circuit board 2003 at the cooperation engagement portion 2074, so that the plurality of electrically conductive terminals 2072 establish electrical connection with the electrically conductive portion 2033 of the first printed circuit board 2003 at the cooperation engagement portion 2074. In some embodiments, the housing 2071 of the electrical connector 2007 may comprise a slot 2071a at the cooperation engagement portion 2074, and a contact portion of the plurality of electrically conductive terminals 2072 may be exposed at the slot 2071a. The second end 2032 of the first printed circuit board 2003 may be inserted into the slot 2071a of the electrical connector 2007, so that the contact portion of the plurality of electrically conductive terminals 2072 establishes an electrical contact with the electrically conductive portion 2033 of the first printed circuit board 2003. In this way, the electrical connector 2007 can mechanically and electrically connect the first printed circuit board 2003 with the second printed circuit board 2005 to achieve a signal and/or power transmission between the first printed circuit board 2003 and the second printed circuit board 2005. The electrical connector 2007 can retain the second end 2032 of the first printed circuit board 2003 relative to the second printed circuit board 2005.

It should be understood that although the electrical connector 2007 is shown as a single piece connector, the specific form of the electrical connector 2007 is not limited to thereto. For example, the electrical connector 2007 may be a two-piece connector that includes a plug connector and a socket connector. Furthermore, it should be understood that the electrical connector 2007 may comprise any suitable mechanism or feature that facilitates fixing the electrical connector 2007 on the second printed circuit board 2005, and/or any suitable mechanism or feature that facilitates connecting the first printed circuit board 2003 to the electrical connector 2007.

The member 2001 according to the exemplary embodiment of the present application may be configured to retain the first printed circuit board 2003 to the second printed circuit board 2005 and release the first printed circuit board 2003 from the second printed circuit board 2005. This member 2001 can help to reliably retain the first printed circuit board 2003 to the second printed circuit board 2005, so as to improve the connection stability among the first printed circuit board 2003, the electrical connector 2007, and the second printed circuit board 2005, and it can achieve the assembly of the first printed circuit board 2003 to the second printed circuit board 2005, as well as the disassembly of the first printed circuit board 2003 from the second printed circuit board 2005.

The member 2001 can implement retaining the first end 2031 of the first printed circuit board 2003 in a releasable manner to the second printed circuit board 2005. The second end 2032 of the first printed circuit board 2003 is electrically connected to the second printed circuit board 2005 through an electrical connector 2007, thereby improving the connection reliability and stability among the first printed circuit board 2003, the electrical connector 2007, and the second printed circuit board 2005.

It should be understood that the member according to the exemplary embodiment of the present application may be used to lock first and second panels arranged parallel to each other, where the first and second panels are not limited to the printed circuit boards described in the exemplary embodiment.

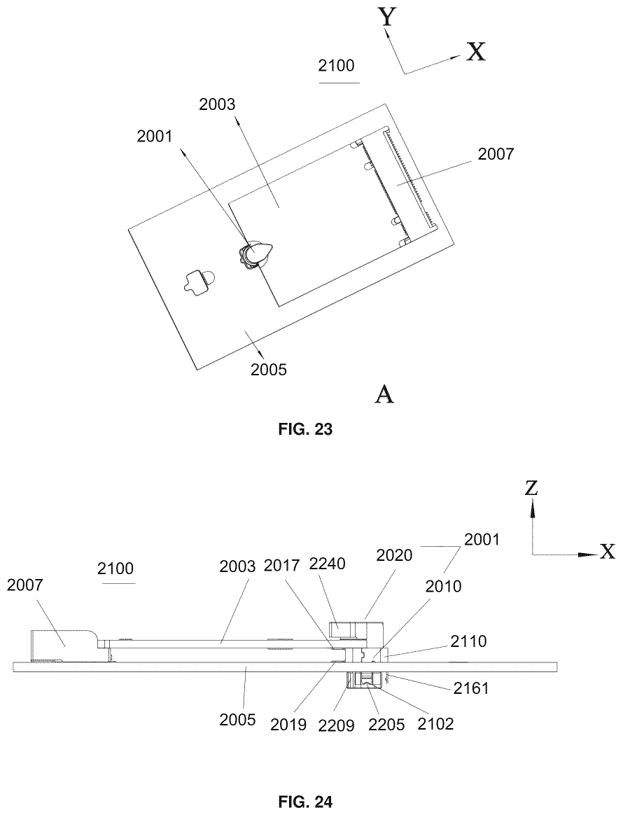

In an exemplary embodiments shown in FIGS. 19 to 24, the member 2001 is movable in a rotatable manner between a locked position A (as shown in FIG. 23; which may sometimes be referred to as “retained position”) in which the member 2001 is inserted through the notch 2301 of the first printed circuit board 2003 and the opening 2501 of the second printed circuit board 2005 and is non-removable with respect to the first printed circuit board 2003 and the second printed circuit board 2005 to retain the first end 2031 of the first printed circuit board 2003 to be fixed with respect to the second printed circuit board 2005, and an unlocked position B (as shown in FIG. 22; which may sometimes be referred to as “released position”) in which the member 2001 is insertable in a removable manner through the notch 2301 of the first printed circuit board 2003 and the opening 2501 of the second printed circuit board 2005, and the first end 2031 of the first printed circuit board 2003 is not fixed with respect to the second printed circuit board 2005.

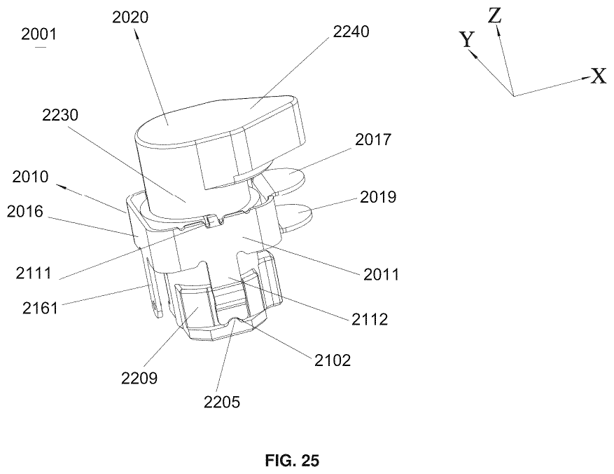

As shown in FIGS. 25, 26, 29 and 30, the member 2001 comprises a first member portion 2020; the first member portion 2020 comprises a columnar portion 2230 that extends in a vertical direction and a stop portion 2240 that protrudes from at least a portion of an upper portion of the columnar portion 2230, and the first member portion 2020 is rotatable such that at least a portion of the stop portion 2240 extends in a horizontal direction beyond the notch 2301 on an upper surface of the first printed circuit board 2003 to prevent a first end 2031 of the first printed circuit board 2003 from moving in a vertical direction Z, and thus the member 2001 is in the locked position A. The first member portion 2020 is rotatable such that the stop portion 2240 moves away from an upper surface of the first printed circuit board 2003, and thus the member 2001 is in the unlocked position B.

According to an exemplary embodiment of the present application, the first printed circuit board 2003 can be fixed to the second circuit board 2005, and the first printed circuit board 2003 (such as a subassembly) can be removed from the second printed circuit board 2005 (such as a motherboard), by rotating the first member portion 2020 of the member 2001, without the need for additional tools and/or processes. The member according to an exemplary embodiment of the present application has a compact structure and occupies a small volume, typically having a small contour, such as a contour of approximately 4.3 mm×4.3 mm×6.7 mm.

Conventionally, an add-in card is usually fixed to the motherboard through threaded connections or soldering, and tools that occupy a large space are used. The fixing operation is complex, and the system is difficult to disassemble after fixation. Furthermore, the conventional device is not reusable and cannot adapt to subassemblies of different lengths. The member in the present application is easy for users to operate, can achieve efficient mounting and dismounting, and is reusable, such that production resources are utilized fully, and costs are reduced. The member 2001 may provide reliable connection and efficient signal transmission between the first printed circuit board 2003, the electronic connector 2007 and the second printed circuit board 2005. The member 2001 is also reusable and can be used to retain add-in cards of different lengths to the second printed circuit board.

In some embodiments, as shown in FIGS. 25 to 28, the member 2001 comprises a second member portion 2010 which comprises a cylindrical portion 2110 formed to extend in the vertical direction Z, and the cylindrical portion 2110 is sleeved on an outer side of the columnar portion 2230 of the first member portion 2020 such that the columnar portion 2230 is rotatable with respect to the cylindrical portion 2110. When the member 2001 is inserted through the notch 2301 of the first printed circuit board 2003 and the opening 2501 of the second printed circuit board 2005, the cylindrical portion 2110 is arranged between the first printed circuit board 2003 and the second printed circuit board 2005.

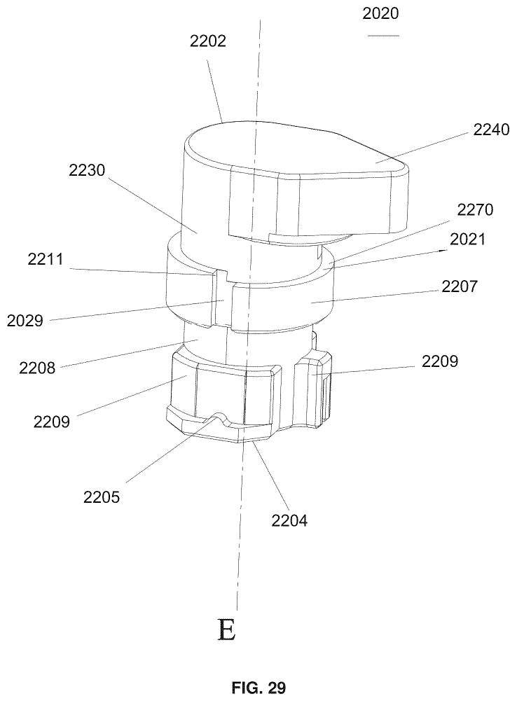

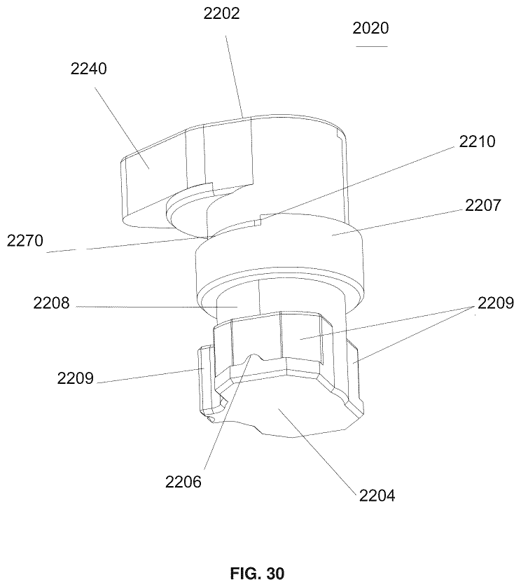

In some embodiments, as shown in FIGS. 29 and 30, the first member portion 2020 comprises a distal end 2202 provided with the stop portion 2240, a proximal end 2204 opposite to the distal end 2202, and a connecting flange 2207 provided between the distal end 2202 and the proximal end 2204, a guide portion 2021 is provided at an upper portion of the connecting flange 2207, the guide portion 2021 comprises a guide surface 2270 extending in a plane substantially perpendicular to the vertical direction Z, and a first stop portion 2210 and a second stop portion 2211 extending in the vertical direction, and the guide portion 2021 is formed as a semi-annular step portion.

The cylindrical portion 2110 comprises a protruding portion 2111 which is movable along the guide surface 2270 between the first stop portion 2210 and the second stop portion 2211 during the rotation of the columnar portion 230 with respect to the cylindrical portion 2110. The protruding portion 2111 is engaged with the first stop portion 2210 when the member 2001 is in the unlocked position B, and the protruding portion 2111 is engaged with the second stop portion 2211 when the member 2001 is in the locked position A.

In some embodiments, the first stop portion 2210 and the second stop portion 2211 may be spaced apart from each other by 180 degrees in a circumferential direction of the columnar portion 2230.

In some embodiments, the connecting flange 2207 comprises a recess 2029 provided adjacent to the second stop portion 2211 (referring to FIG. 29), the recess 2029 extends through the connecting flange 2207 in the vertical direction. When the first member portion 2020 is assembled with the second member portion 2010, the protruding portion 2111 is inserted through the recess 2029 of the first member portion 2020, that is, the protruding portion 2111 moves from the lower portion of the recess 2029 towards the upper portion of the recess 2029, and then enters the guide surface 2270 of the guide portion 2021. This configuration avoids damage to the outer circumferential surface of the first member portion 2020 caused by the protruding portion 2111 in the process that the first member portion 2020 and the second member portion 2010 are assembled and separated.

In some embodiments, the stop portion 2240 of the first member portion 2020 protrudes in a horizontal direction X towards a side on which the guide portion 2021 is located, and is tapered in a direction away from an axis of rotation of the first member portion 2020. For example, in one example, the stop portion 2240 has a water droplet shape in a cross-section perpendicular to the vertical direction. The configuration of the stop portion occupies less space and is convenient for manual operation by the operator.

It should be understood that the structure of the stop portion 2240 is not limited to the structure shown in the figures, but is adjustable according to specific circumstances. For example, the stop portion may be formed into a sectoral knob, a polygonal knob, a pointer shaped knob, an irregular knob, etc.

In some embodiments, as shown in FIGS. 27 to 30, the cylindrical portion 2110 is approximately square-shaped, and a central axis of the cylindrical portion 2110 coincides with an axis of rotation E of the columnar portion 2230. The cylindrical portion 2110 comprises a first sidewall 2011 and a second sidewall 2012 opposite to the first sidewall 2011 in a transverse direction Y perpendicular to the vertical direction Z, and the protruding portion 2111 is provided at a central portion of an upper edge portion of the first sidewall 2011 and protrudes towards an inner side of the cylindrical portion 2110.

In addition, the cylindrical portion 2110 comprises a third sidewall 2015 and a fourth sidewall 2016 opposite to the third sidewall 2015 in a horizontal direction X perpendicular to the vertical direction Z and the transverse direction Y, the third sidewall 2015 is provided with a first cantilever portion 2017 and a second cantilever section 2019 which both extend along a plane perpendicular to the vertical direction Z and are spaced apart from each other, and the first cantilever portion 2017 is provided above the second cantilever portion 2019 in the vertical direction.

As shown in FIG. 27, the first cantilever portion 2017 comprises a first surface 2171 and a second surface 2173 opposite to the first surface. The second cantilever portion 2019 comprises a third surface 2191 facing the second surface of the first cantilever portion 2017 and a fourth surface 2193 opposite to the third surface 2191, and when the member 2001 is inserted through the notch 2301 of the first printed circuit board 2003 and the opening 2501 of the second printed circuit board 2005, the first surface 2171 of the first cantilever portion 2017 is disposed against a lower surface 2003b of the first printed circuit board 2003, and the fourth surface 2193 of the second cantilevered portion 2019 is disposed against an upper surface 2005a of the second printed circuit board 2005. As illustrated, the first cantilever portion 2017 and the second cantilever portion 2019 have a semi-circular shape in a cross-section perpendicular to the vertical direction Z. A distance between the first cantilever portion 2017 and the second cantilever portion 2019 may be provided to be equal to a distance between the first printed circuit board 2003 and the second printed circuit board 2005.

As illustrated, the first cantilever portion 2017, the second cantilever portion 2019, and the third sidewall 2015 may be formed integrally, for example, formed integrally by stamping and bending a metal blank. It should be understood that the two cantilever portions and the third sidewall 2015 may be formed independently of one another, and the two cantilever portions are detachably connected with the third sidewall 2015. A distance between the first cantilever portion 2017 and the second cantilever portion 2019 may be provided to be adjustable.

It should be understood that the size, the distance, the position, and the arrangement mode of the first cantilever portion 2017 and the second cantilever portion 2019 are not limited to the specific embodiment shown, and can be adjusted as actually needed. For example, the first cantilever portion 2017 and the second cantilever portion 2019 of the present application have the following cross-sectional shapes in a cross-section perpendicular to the vertical direction Z: trapezoidal, sectoral, square, or irregular shapes.

In some embodiments, as shown in FIGS. 27 and 28, the second member portion 2010 further comprises a first resilient portion 2112 extending downwards in the vertical direction at a central portion of the first sidewall 2011, and a second resilient portion 2114 extending downwards in the vertical direction at a central portion of the second sidewall 2012, and the first resilient portion 2112 and the second resilient portion 2114 are mirrored about a plane perpendicular to the transversal direction Y and passing through a transverse central axis of the second member portion 2010. In some examples, the first resilient portion 2112 is integrally formed with the first sidewall 2011, and the second resilient portion 2114 is integrally formed with the second sidewall 2012.

It should be understood that the number, the location and the arrangement mode of the resilient portion of the second member portion 2010 are not limited to the specific embodiment shown, and can be adjusted as actually needed.

The first member portion 2020 is provided with a first engagement portion and a second engagement portion associated with the first resilient portion 2112 and the second resilient portion 2114. When the member is in the unlocked position or the locked position, one of the first resilient portion 2112 and the second resilient portion 2114 is engaged with the first engagement portion and the other of the first resilient portion 2112 and the second resilient portion 2114 is engaged with the second engagement portion. Through this configuration, when the member is in the unlocked position or in the locked position, the first member portion 2020 may be held to be fixed relative to the second member portion 2010 to reduce the risk of unintentional rotation of the first member portion 2020.

In some embodiments, the first resilient portion 2112 comprises a first end connected to a lower edge portion of the first sidewall 2011, a second end opposite to the first end, and an arch portion provided between the first end and the second end. When the member is in the unlocked position or the locked position, the second end of the first resilient portion 2112 cooperates with the first engagement portion or the second engagement portion of the first member portion 2020. The second resilient portion 2114 may have substantively the same structure as the first resilient portion 2112. An arch portion provided on each resilient portion facilitates the absorption of impact and vibration, which is conducive to the reliable engagement between the resilient portion and the first member portion 2020, and improves the structural stability of the member.

In some embodiments, as shown in FIGS. 25 to 30, a first concave portion 2102 is provided at the second end of the first resilient portion 2112 and a second concave portion 2104 is provided at the second end of the second resilient portion 2114. The first engagement portion of the first member portion 2020 comprises a first convex portion 2205 provided at the proximal end 2204, the second engagement portion of the first member portion 2020 comprises a second convex portion 2206 provided at the proximal end 2204, and the first convex portion 2205 and the second convex portion 2206 may be provided to be spaced apart from each other by 180 degrees in a circumferential direction of the first member portion 2020. When the member is in the unlocked position or the locked position, one of the first concave portion 2102 and the second concave portion 2104 is engaged with the first convex portion 2205, and the other of the first concave portion 2102 and the second concave portion 2104 is engaged with the second convex portion 2206.

It should be understood that the engaging mode where the resilient portion is engaged with the first member portion 2020 of the present application is not limited thereto. When the member is in the unlocked position or the locked position, the first resilient portion and the second resilient portion may cooperate with the first member portion 2020 by any other suitable means to hold the first member portion 2020 to be fixed in place relative to the second member portion 2010.

In some embodiments, a strip portion 2161 extending downward in the vertical direction is formed at a lower edge portion of the fourth sidewall 2016 of the cylindrical portion 2110, and during the rotation of the first member portion 2020 with respect to the second member portion 2010, a free end of the strip portion 2161 may be in contact with and slide past the first convex portion 2205 or the second convex portion 2206.

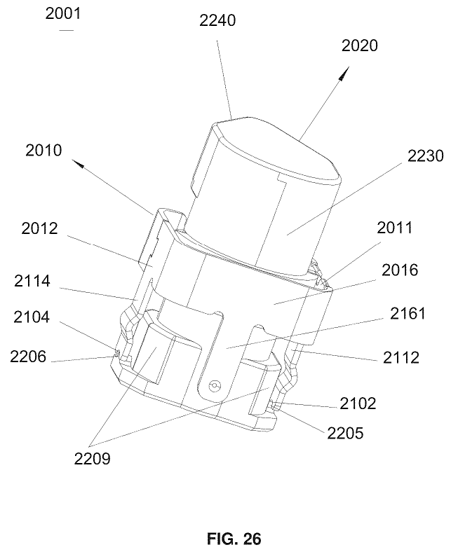

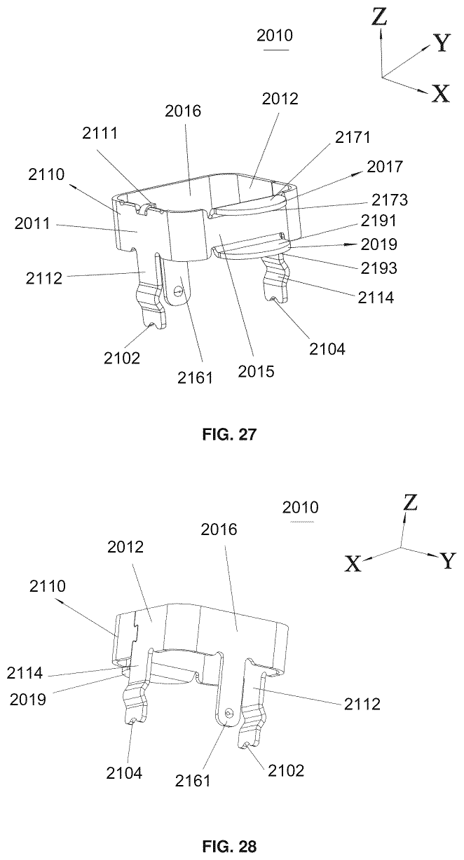

For example, in the process that the member 2001 is switched from the unlocked position B to the locked position A, when the member 2001 is initially in the unlocked position B, the protruding portion 2111 of the second member portion 2010 is disposed against the first stop portion 2210 of the guide portion 2021, the first concave portion 2102 of the first resilient portion 2112 is engaged with the second convex portion 2206, and the second concave portion 2104 of the second resilient portion 2114 is engaged with the first convex portion 2205. When the operator begins to rotate the first member portion 2020 in a counterclockwise direction F relative to the second member portion 2010 (referring to FIG. 22), the first stop portion 2210 moves away from the protruding portion 2111, the first concave portion 2102 is disengaged from the second convex portion 2206, and the second concave portion 2104 is disengaged from the first convex portion 2205. When the first member portion 2020 rotates 90 degrees relative to the second member portion 2010, the free end of the strip portion 2161 contacts the first convex portion 2205 and generates a small amount of resistance, so that the operator feels the resistance and receives information that the first member portion 2020 is switching positions. Under the continuous application of force by the operator, the strip portion 2161 slides past the first convex portion 2205. The first member portion 2020 continues to rotate counterclockwise relative to the second member portion 2010 until the protruding portion 2111 is disposed against the second stop portion 2211 of the guide portion 2021 (rotating approximately 180 degrees relative to the unlocked position), thereby keeping the member in the locked position. In the locked position A, the first concave portion 2102 of the first resilient portion 2112 is engaged with the first convex portion 2205, and the second concave portion 2104 of the second resilient portion 2114 is engaged with the second convex portion 2206 (as shown in FIG. 26). When the member 2001 is switched from the unlocked position B to the locked position A, the strip portion 2161 provides the operator with information about the rotational status of the first member portion 2020. If the operator does not feel the contact between the strip portion 2161 and the corresponding convex portion, the operator can determine that the first member portion 2020 may be disengaged from the mounting component 2010. In this case, the operator can adjust the operation in a timely manner and perform additional checks on the member 2001. It should be understood that the process of operating the member 2001 from the locked position A to the unlocked position B is opposite to the locking process described earlier.

In some embodiments, as shown in FIGS. 24, 26, 29, and 30, a plurality of protruding ribs 2209 are provided adjacent to the proximal end 2204 of the first member portion 2020, the plurality of protruding ribs 2209 are arranged in a circumferential direction on an outer peripheral portion of the columnar portion 2230 of the first member portion 2020 and protrude outward in a radial direction. When the member 2001 is inserted through the opening 2501 of the second printed circuit board 2005, an upper surface of the plurality of protruding ribs 2209 in the vertical direction at least partially is in contact with a lower surface of the second printed circuit board 2005, thereby tightly retaining the lower surface of the second printed circuit board 2005 to the protruding ribs 2209. In some embodiments, in a cross-section perpendicular to the vertical direction Y of the member 2001, the plurality of protruding ribs 2209 are arranged at inner sides of the cylindrical portion 2110 in a radial direction. In other words, the outer contour shape of the plurality of protruding ribs 2209 does not extend beyond the inner surface of the cylindrical portion 2110 in a radial direction.

In the embodiments shown in FIGS. 29 and 30, three protruding ribs 2209 are shown, and two of the protruding ribs 2209 are provided on opposite sides of the columnar portion 2230 in the transverse direction Y, and are mirrored about a plane perpendicular to the transverse direction Y and passing through an axis of rotation E of the columnar portion 2230. It should be understood that the size, the number, the position and the arrangement mode of the protruding rib are not limited to the specific embodiment shown, and can be adjusted as actually needed.

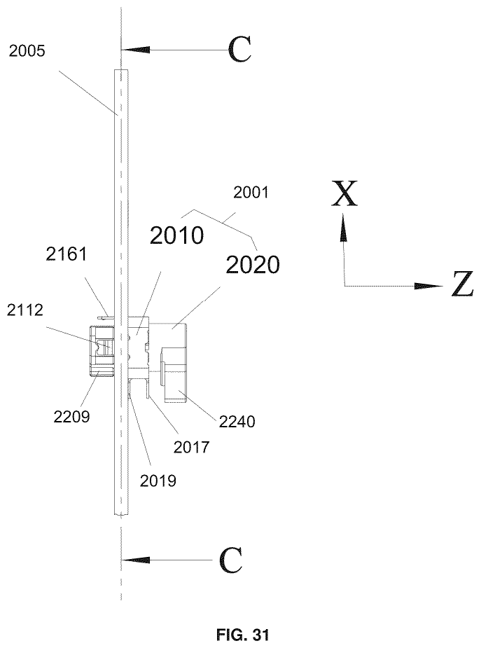

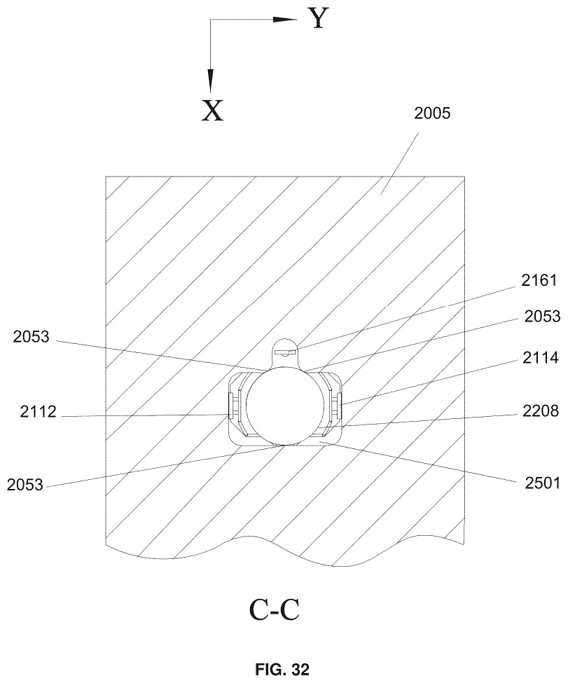

In some embodiments, as shown in FIGS. 29 and 30, the columnar portion 2230 comprises a mounting portion 2208 corresponding to the opening 2501 of the second printed circuit board 2005, the mounting portion 2208 is provided between the connecting flange 2207 and the protruding ribs 2209 in the vertical direction. As shown in FIGS. 31 and 32, an inner surface of the opening 2501 of the second printed circuit board 2005 comprises a plurality of rotational position-limiting portions 2053 capable of being in contact with an outer circumferential surface of the mounting portion 2208, at least one of the plurality of rotational position-limiting portions 2053 is formed to have an arcuate shape, and the mounting portion 2208 has a size in the vertical direction which corresponds to a thickness of the second printed circuit board 2005, for example, approximately equal to the thickness of the second printed circuit board 2005.

In the embodiment shown in FIG. 32, the inner surface of the opening 2501 of the second printed circuit board 2005 comprises three rotational position-limiting portions, which define the range of motion of the columnar portion 2230 of the first member portion 2020 to ensure that the columnar portion 2230 of the first member portion 2020 does not shift during the rotation process. It should be understood that the number, the location and the arrangement mode of the rotational position-limiting portion of the opening 2501 are not limited to the specific embodiment shown, and can be adjusted as actually needed.

In some embodiments, as shown in FIG. 32, the opening 2501 of the second printed circuit board 2005 is formed to have approximately a T-shaped shape, and has a first elongate portion and a second elongate portion perpendicular to the first elongate portion. When the member 2001 is inserted through the opening 2501 of the second printed circuit board 2005 and is in the unlocked position or in the locked position, the member 2001 has a dimension in the transverse direction Y, which corresponds to a dimension of the first elongate portion in the transverse direction Y. In a projection plane of the electronic system 2100 perpendicular to the vertical direction Y, the strip portion 2161 of the second member portion 2010 is arranged in the second elongate portion of the opening 2501.

In some embodiments, the first member portion 2020 is configured to be electrically insulating and the second member portion 2010 is configured to be electrically conductive. For example, the second member portion 2010 may be formed of electrically conductive materials such as copper or stainless steel. The first member portion 2020 may be made of insulating materials. Insulating materials suitable for manufacturing the first member portion 2020 include, but are not limited to, plastics, nylon, liquid crystal polymer (LCP), Polyphenylene sulfide (PPS), high-temperature nylon or polyphenylene oxide (PPO) or polypropylene (PP).

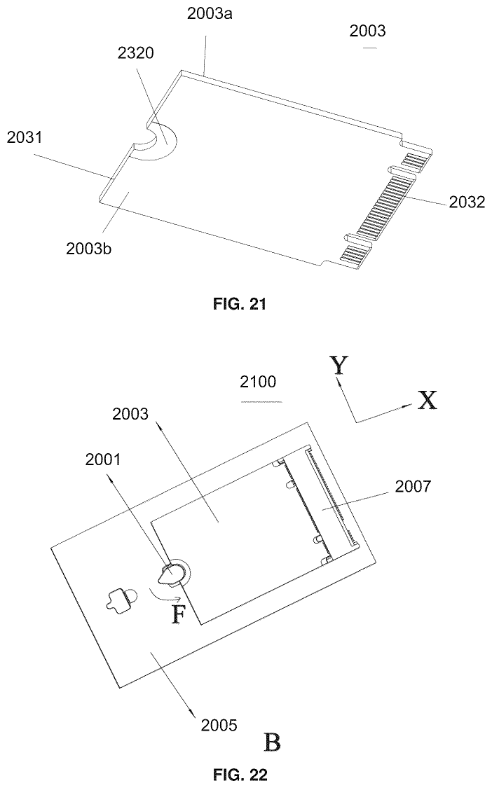

In some embodiments, the first printed circuit board 2003 may comprise a first electrically conductive portion 2320 provided on a lower surface of the first printed circuit board 2003 (referring to FIG. 21), where the first electrically conductive portion 2320 is provided adjacent to the notch 2301. As shown in FIG. 24, when the member 2001 is inserted through the notch 2301 of the first printed circuit board 2003 and the opening 2501 of the second printed circuit board 2005, a first surface 2171 of the first cantilever portion 2017 of the second member portion 2010 is engaged with and thus establishes an electrical contact with the first electrically conductive portion 2320.

In some embodiments, the second printed circuit board 2005 comprises a second electrically conductive portion 2520 provided on an upper surface of the second printed circuit board 2005 and adjacent to the opening 2501 (referring to FIG. 20). When the member 2001 is inserted through the notch 2301 of the first printed circuit board 2003 and the opening 2501 of the second printed circuit board 2005, a fourth surface 2193 of the second cantilevered portion 2019 of the second member portion 2010 is engaged with and thus establishes an electrical contact with the second electrically conductive portion 2520. In some examples, one of the first electrically conductive portion 2320 and the second electrically conductive portion 2520 may be formed to have a trapezoidal, sectoral, square, semicircular, or annular shape.

In this way, the electrically conductive portion 2320 of the first printed circuit board 2003 may be electrically connected with the second electrically conductive portion 2520 of the second printed circuit board 2005 by using the second member portion 2010. The first cantilever portion 2017 and the second cantilever portion 2019 of the second member portion 2010 are designed to have a larger contact area in contact with the corresponding circuit board, improving connection reliability. In addition, this configuration may provide a grounding path between the first printed circuit board 2003 and the second printed circuit board 2005 to achieve a design that avoids electromagnetic interference (EMI).

According to some exemplary embodiments of the present application, there is provided a method for operating a member, which method may comprise: providing a first panel, a notch 2301 being provided at a first end of the first panel; providing a second panel, an opening 2501 being provided in the second panel; providing a member 2001 which is movable in a rotatable manner between a locked position A and an unlocked position B; aligning the member 2001 in a vertical direction Z with the notch 2301 of the first panel and the opening 2501 of the second panel; rotating the member 2001 to the unlocked position B, and inserting the member 2001 through the notch 2301 of the first panel and the opening 2501 of the second panel, and rotating the member 2001 to the locked position A so that the member 2001 is irremovable with respect to the first panel and the second panel, thereby retaining the first end 2031 of the first panel to be fixed with respect to the second panel.

In some embodiments of the present application, providing the member 2001 may comprise: configuring the member 2001 to comprise a first member portion 2020 comprising a columnar portion 2230 extending in a vertical direction, and a stop portion 2240 protruding from at least a portion of an upper portion of the columnar portion 2230.

Rotating the member 2001 to the locked position A may comprise: the first member portion 2020 is rotated such that at least a portion of the stop portion 2240 extends in a horizontal direction beyond the notch 2301 on an upper surface of the first panel to prevent a first end 2031 of the first panel from moving in a vertical direction Z, and thus the member 2001 is in the locked position. Rotating the member 2001 to the unlocked position B may comprise: the first member portion 2020 is rotated such that the stop portion 2240 moves away from an upper surface of the first panel, and thus the member 2001 is in the unlocked position.

In some embodiments of the present application, providing the member 2001 may comprise: configuring the member 2001 to comprise a second member portion 2010 comprising a cylindrical portion 2110 formed to extend in the vertical direction Z, the cylindrical portion 2110 being sleeved on an outer side of the columnar portion 2230 of the first member portion 2020 and inserting the member 2001 through the notch 2301 of the first panel and the opening 2501 of the second panel comprises: arranging the cylindrical portion 2110 between the first panel and the second panel.

In some embodiments of the present application, providing the member 2001 may comprise: configuring the first member portion 2020 to comprise a guide portion 2021 provided along an outer circumferential portion of the first member portion 2020, the guide portion 2021 comprising a guide surface 2270 extending in a plane substantially perpendicular to the vertical direction Z, the guide portion 2021 comprising a first stop portion 2210 and a second stop portion 2211 extending in the vertical direction; and configuring the second member portion 2010 to comprise a protruding portion 2111 protruding towards an inner side of the second member portion 2010; and rotating the member 2001 to the locked position may comprise: rotating the first member portion 2020 with respect to the second member portion 2010 in such a way that the protruding portion 2111 moves away from the first stop portion 2210 along the guide surface 2270 until the protruding portion 2111 abuts against the second stop portion 2211.

In some embodiments of the present application, providing the member may comprise: configuring the cylindrical portion 2110 of the member 2001 to comprise a first sidewall 2011 and a second sidewall 2012 opposite to the first sidewall 2011 in a transverse direction Y perpendicular to the vertical direction Z, and providing the protruding portion 2111 at a central portion of an upper edge portion of the first sidewall 2011, and configuring the cylindrical portion 2110 of the second member portion 2010 to comprise a third sidewall 2015 and a fourth sidewall 2016 opposite to the third sidewall 2015 in a horizontal direction X, the third sidewall 2015 being provided with a first cantilever portion 2017 and a second cantilever portion 2019 which both extend in a plane perpendicular to the vertical direction Z and are spaced apart from each other, the first cantilever portion 2017 being provided above the second cantilever portion 2019 in the vertical direction, the first cantilever portion 2017 comprising a first surface 2171 and a second surface 2173 opposite to the first surface, the second cantilever portion 2019 comprising a third surface 2191 facing the second surface of the first cantilever portion 2017 and a fourth surface 2193 opposite to the third surface; and inserting the member 2001 through the notch 2301 of the first panel and the opening 2501 of the second panel comprises: resting the first surface 2171 of the first cantilever portion 2017 against a lower surface of the first panel; and resting the fourth surface 2193 of the second cantilever portion 2019 against an upper surface of the second panel.

In some embodiments of the present application, the method may comprise: rotating the member 2001 to the unlocked position B to remove the member 2001 from the notch 2301 of the first panel and the opening 2501 of the second panel, when the first end 2031 of the first panel is held to be fixed with respect to the second panel.

In some embodiments of the present application, the method may comprise: configuring the first panel as a first printed circuit board 2003, and configuring the second panel as a second printed circuit board 2005.

In some embodiments of the present application, the method may comprise: providing a first electrically conductive portion 2320 on a lower surface of the first printed circuit board 2003, where the first electrically conductive portion 2320 is provided adjacent to the notch 2301, and providing a second electrically conductive portion 2520 on an upper surface of the second printed circuit board 2005, where the second electrically conductive portion 2520 is provided adjacent to the opening 2501. Inserting the member 2001 through the notch 2301 of the first panel and the opening 2501 of the second panel comprises: a first surface 2171 of the first cantilever portion 2017 of the second member portion 2010 being engaged with and establishing an electrical contact with the first electrically conductive portion 2320; and a fourth surface 2193 of the second cantilevered portion 2019 of the second member portion 2010 being engaged with the second electrically conductive portion 2520 and establishing an electrical contact with the second electrically conductive portion 2520.

With the method for operating a member provided by the present application, a user can keep the first panel fixed relative to the second panel in a releasable manner by means of a member without the need for additional tools and/or processes, where the operating process is a simple and reliable. The member can be easily mounted and dismounted and is reusable. For example, the member can be easily removed from one opening of the second panel and mounted into another opening of the second panel, enabling for cooperation with a first panel having a different length.

It should be understood that the method for operating the member of the present application is not limited to the method described in the above specific embodiment, and that the individual steps described involve only a non-exhaustive list and do not have a specific order, and the order of the steps can be adjusted by those skilled in the art as actually needed.

Having thus described several aspects of several embodiments of a member for retaining and releasing a first circuit board to and from a second circuit board, it is to be appreciated that various alterations, modifications, and improvements will readily occur to those skilled in the art. Such alterations, modifications, and improvements are intended to be part of this disclosure, and are intended to be within the spirit and scope of the invention. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

In the claims, as well as in the specification above, use of ordinal terms such as “first,” “second,” “third,” etc. does not by itself connote any priority, precedence, or order of one element over another or the temporal order in which acts of a method are performed, but are used merely as labels to distinguish one element having a certain name from another element having a same name (but for use of the ordinal term) to distinguish the elements.

What is claimed is:

1. A member configured to retain and release a first circuit board to and from a second circuit board, the member comprising:
a retaining portion configured to extend through an end of the first circuit board, the retaining portion comprising a sub-portion configured to be movable with respect to the end of the first circuit board between a first position for retaining the end of the first circuit board and a second position for releasing the end of the first circuit board; and
a mounting portion opposite the retaining portion and configured to extend into an opening of the second circuit board.

2. The member of claim 1, wherein the mounting portion comprises:
a first engaging portion configured to engage with a first surface of the second circuit board; and
a second engaging portion configured to engage with a second surface of the second circuit board opposite to the first surface to secure the member to the second circuit board.

3. The member of claim 2, wherein:
the first engaging portion comprises a pair of beams disposed on opposite sides of the member; and
the second engaging portion comprises a pair of projections protruding toward respective beams of the pair of beams.

4. The member of claim 1, wherein:
the sub-portion of the retaining portion comprises one or more conductive contact portions configured to make contact with a conductive portion of the first circuit board.

5. The member of claim 1, wherein:
the mounting portion comprises a plurality of beams configured to abut a boundary of the opening of the second circuit board so as to secure the member to the second circuit board.

6. The member of claim 5, wherein:
the plurality of beams are disposed in rotational symmetry.

7. The member of claim 1, wherein:
the sub-portion of the retaining portion comprises a protrusion disposed above a surface of the first circuit board.

8. The member of claim 8, wherein:
the retaining portion comprises a plurality of beams protruding away from the mounting portion to support the first circuit board.

9. An electronic system comprising:
a first circuit board;
a second circuit board comprising an opening extending therethrough; and
a member comprising a first portion, the first portion comprising a first sub-portion engaging the end of the first circuit board, and a second sub-portion engaging the opening of the second circuit board,
wherein the first portion is insulative.

10. The electronic system of claim 9, wherein:
the member comprises a semicircular portion above the platform, and a latch movable between a retained position in which the latch is above the first circuit board and a released position in which the latch is offset from the first circuit board.

11. The electronic system of claim 9, wherein:
the member comprises a plurality of beams abutting a boundary of the opening of the second circuit board so as to secure the member to the second circuit board.

12. The electronic system of claim 9, wherein:
the member comprises a second portion electrically coupling the first circuit board to the second circuit board.

13. The electronic system of claim 12, wherein:
the second portion of the member comprises a plurality of first contact portions coupled to a conductive portion of the first circuit board and a plurality of second contact portions coupled to a conductive portion of the second circuit board.

14. The electronic system of claim 9, wherein:
the first circuit board comprises a first end and a second end;
the first end of the first circuit board is inserted into an electrical connector mounted on the second circuit board; and
the second end of the first circuit board is secured to the second circuit board by the member.

15. A method of operating a member configured for retaining and releasing a first circuit board to and from a second circuit board, the method comprising:
attaching the member to the second circuit board comprising engaging a mounting portion of the member with an opening of the second circuit board; and
attaching the member to a distal end of the first circuit board comprising moving a retaining portion of the member from a released position to a retained position.

16. The method of claim 15, wherein:
the opening is a first opening;
the second circuit board comprises a second opening; and
the method further comprises prior to engaging the mounting portion of the member with the first opening, removing the member from the second opening.

17. The method of claim 15, wherein:
attaching the member to the second circuit board comprises sliding the member along a first surface of the opening of the second circuit board and then pushing the member toward a second surface of the opening facing the first surface until that the member abuts against the second surface.

18. The method of claim 15, wherein:
attaching the member to a distal end of the first circuit board comprises pushing the first printed circuit board toward the second printed circuit board until that one or more portions of the member engage a surface of the first circuit board.

19. The method of claim 15, wherein:
engaging the mounting portion of the member with the opening of the second printed circuit board comprises compressing a plurality of beams of the member with a boundary of the opening.

20. The method of claim 15, wherein:
moving the retaining portion of the member from the released position to the retained position comprises rotating a retaining portion until it is adjacent and/or engages a surface of the first circuit board.
